(19) United States
(12) Patent Application Publication
(10) Pub. No.: US 2024/0363712 A1
(43) Pub. Date: Oct. 31, 2024

(54) SEMICONDUCTOR DEVICES

(71) Applicant: Samsung Electronics Co., Ltd., Suwon-si (KR)

(72) Inventors: Sang Moon Lee, Suwon-si (KR); Jin Bum Kim, Suwon-si (KR); Hyo Jin Kim, Suwon-si (KR); Yong Jun Nam, Suwon-si (KR); In Geon Hwang, Suwon-si (KR)

(21) Appl. No.: 18/505,279

(22) Filed: Nov. 9, 2023

(30) Foreign Application Priority Data
Apr. 28, 2023 (KR) 10-2023-0056021

(51) Int. Cl. H01L 29/423; H01L 21/8238; H01L 27/092; H01L 29/06; H01L 29/08; H01L 29/66; H01L 29/775; H01L 29/786

(52) U.S. Cl. CPC H01L 29/42392; H01L 21/823807; H01L 21/823842; H01L 27/092; H01L 29/0673; H01L 29/0847; H01L 29/66439; H01L 29/66545; H01L 29/6656; H01L 29/775; H01L 29/78696

(57) ABSTRACT

A semiconductor device may include a substrate, an active pattern extended in a first horizontal direction on the substrate, a plurality of nanosheets stacked and spaced apart from each other in a vertical direction on the active pattern, a gate electrode extended in a second horizontal direction different from the first horizontal direction on the active pattern, the gate electrode surrounding the plurality of nanosheets, a source/drain region on both sides of the plurality of nanosheets in the first horizontal direction on the active pattern, a gate insulating layer between the plurality of nanosheets and the gate electrode, and a doping layer between the plurality of nanosheets and the gate insulating layer, the doping layer including silicon (Si) or silicon germanium (SiGe) and doped with a doping material, at least a portion of the doping layer overlapping an uppermost nanosheet of the plurality of nanosheets in the first horizontal direction.

### CROSS-REFERENCE TO RELATED APPLICATION

This application claims priority from Korean Patent Application No. 10-2023-0056021, filed on Apr. 28, 2023, in the Korean Intellectual Property Office, and all the benefits accruing therefrom under 35 U.S.C. § 119, and the entire contents of the above-identified application are herein incorporated by reference.

### TECHNICAL FIELD

The present disclosure relates to semiconductor devices, and more particularly, to semiconductor devices that include a multi-bridge channel field effect transistor (MBCFET™).

### BACKGROUND

Scaling techniques for increasing a density of an integrated circuit device have been suggested, such as a multi-gate transistor in which a silicon body having a fin or nano-wire shape is formed on a substrate and a gate is formed on a surface of the silicon body.

Since this multi-gate transistor uses a three-dimensional channel, it may be relatively easy to scale the multi-gate transistor. Also, even though a gate length of the multi-gate transistor is not increased, a current control capability may be improved. In addition, a short channel effect (SCE) in which a potential of a channel region is affected by a drain voltage may be suppressed effectively.

### SUMMARY

Some aspects of the present disclosure provide semiconductor devices that control (e.g., control effectively) a threshold voltage of a PMOS transistor by providing a doping layer, which includes silicon (Si) or silicon germanium (SiGe), which is doped with an n-type doping material, on a surface of a plurality of nanosheets corresponding to a channel region of the PMOS transistor.

Some aspects of the present disclosure provide semiconductor devices that control (e.g., control effectively) a threshold voltage of an NMOS transistor by a doping layer, which includes silicon (Si) or silicon germanium (SiGe), which is doped with a p-type doping material, on a surface of a plurality of nanosheets corresponding to a channel region of the NMOS transistor.

According to some embodiments of the present disclosure, there is provided a semiconductor device, comprising a substrate, an active pattern extended in a first horizontal direction on the substrate, a plurality of nanosheets stacked to be spaced apart from each other in a vertical direction on the active pattern, a gate electrode extended in a second horizontal direction different from the first horizontal direction on the active pattern, the gate electrode surrounding the plurality of nanosheets, a source/drain region on both sides of the plurality of nanosheets in the first horizontal direction on the active pattern, a gate insulating layer between the plurality of nanosheets and the gate electrode, and a doping layer between the plurality of nanosheets and the gate insulating layer, the doping layer including silicon (Si) or silicon germanium (SiGe), the doping layer doped with a doping material, at least a portion of the doping layer overlapping an uppermost nanosheet of the plurality of nanosheets in the first horizontal direction.

According to some embodiments of the present disclosure, there is provided a semiconductor device, comprising a substrate in which an NMOS region and a PMOS region are defined, a first active pattern extended in a first horizontal direction on the NMOS region of the substrate, a second active pattern extended in the first horizontal direction on the PMOS region of the substrate, a first plurality of nanosheets stacked to be spaced apart from each other in a vertical direction on the first active pattern, a second plurality of nanosheets stacked to be spaced apart from each other in the vertical direction on the second active pattern, a first gate electrode extended in a second horizontal direction different from the first horizontal direction on the first active pattern, the first gate electrode surrounding the first plurality of nanosheets, a second gate electrode extended in the second horizontal direction on the second active pattern, the second gate electrode surrounding the second plurality of nanosheets, a first source/drain region on both sides of the first plurality of nanosheets in the first horizontal direction on the first active pattern, a second source/drain region on both sides of the second plurality of nanosheets in the first horizontal direction on the second active pattern, a first gate insulating layer between the first plurality of nanosheets and the first gate electrode, a second gate insulating layer between the second plurality of nanosheets and the second gate electrode, and a first doping layer between the second plurality of nanosheets and the second gate insulating layer, the first doping layer including silicon (Si) or silicon germanium (SiGe), the first doping layer doped with an n-type doping material, at least a portion of the first doping layer overlapping an uppermost nanosheet of the second plurality of nanosheets in the first horizontal direction.

According to some embodiments of the present disclosure, there is provided a semiconductor device, comprising a substrate in which an NMOS region and a PMOS region are defined, a first active pattern extended in a first horizontal direction on the NMOS region of the substrate, a second active pattern extended in the first horizontal direction on the PMOS region of the substrate, a first plurality of nanosheets stacked to be spaced apart from each other in a vertical direction on the first active pattern, a second plurality of nanosheets stacked to be spaced apart from each other in the vertical direction on the second active pattern, a first gate electrode extended in a second horizontal direction different from the first horizontal direction on the first active pattern, the first gate electrode surrounding the first plurality of nanosheets, a second gate electrode extended in the second horizontal direction on the second active pattern, the second gate electrode surrounding the second plurality of nanosheets, a first source/drain region on both sides of the first plurality of nanosheets in the first horizontal direction on the first active pattern, a second source/drain region on both sides of the second plurality of nanosheets in the first horizontal direction on the second active pattern, a first gate insulating layer between the first plurality of nanosheets and the first gate electrode, a second gate insulating layer between the second plurality of nanosheets and the second gate electrode, and a first doping layer between the first plurality of nanosheets and the first gate insulating layer, the first doping layer including silicon (Si) or silicon germanium (SiGe), the first doping layer doped with a p-type doping material, at least a portion of the first doping layer overlapping an uppermost nanosheet of the first plurality of nanosheets in the first horizontal direction.

The aspects, objects, and examples of embodiments of the present disclosure are not limited to those mentioned above, and additional aspects, objects, and examples of embodiments of the present disclosure, even if not explicitly mentioned herein, will be clearly understood by those skilled in the art from the following description of the present disclosure.

### BRIEF DESCRIPTION OF THE DRAWINGS

The above and other aspects and features of the present disclosure will become more apparent by describing in detail some examples of embodiments thereof with reference to the attached drawings, in which:

FIG. 1 is a schematic layout view illustrating a semiconductor device according to some embodiments of the present disclosure;

FIG. 2 is a cross-sectional view taken along lines A-A′ and B-B′ of FIG. 1;

FIG. 3 is an enlarged view illustrating a region R1 of FIG. 1;

FIG. 4 is a cross-sectional view taken along lines C-C′ and D-D′ of FIG. 1;

FIGS. 5 to 25 are views illustrating intermediate steps to describe a method for fabricating a semiconductor device according to some embodiments of the present disclosure;

FIGS. 26 and 27 are cross-sectional views illustrating a semiconductor device according to some embodiments of the present disclosure;

FIGS. 28 and 29 are cross-sectional views illustrating a semiconductor device according to some embodiments of the present disclosure;

FIG. 30 is a cross-sectional view illustrating a semiconductor device according to some embodiments of the present disclosure;

FIG. 31 is an enlarged view illustrating a region R2 of FIG. 30;

FIGS. 32 to 36 are views illustrating intermediate steps to describe a method for fabricating a semiconductor device according to some embodiments of the present disclosure;

FIG. 37 is a cross-sectional view illustrating a semiconductor device according to some embodiments of the present disclosure;

FIG. 38 is a cross-sectional view illustrating a semiconductor device according to some embodiments of the present disclosure;

FIG. 39 is a cross-sectional view illustrating a semiconductor device according to some embodiments of the present disclosure;

FIG. 40 is a cross-sectional view illustrating a semiconductor device according to some embodiments of the present disclosure; and

FIG. 41 is a cross-sectional view illustrating a semiconductor device according to some embodiments of the present disclosure.

### DETAILED DESCRIPTION OF THE DISCLOSURE

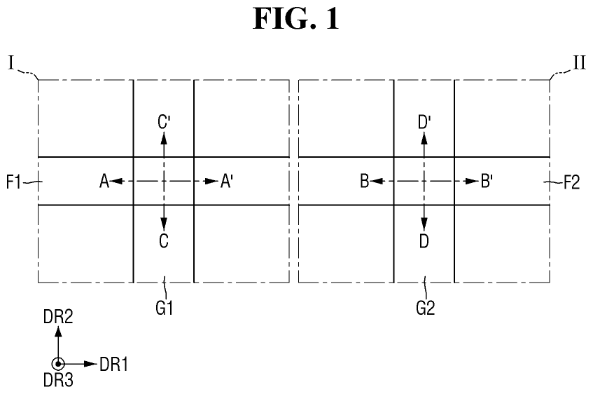

Hereinafter, the semiconductor device according to some embodiments of the present disclosure will be described with reference to FIGS. 1 to 4.

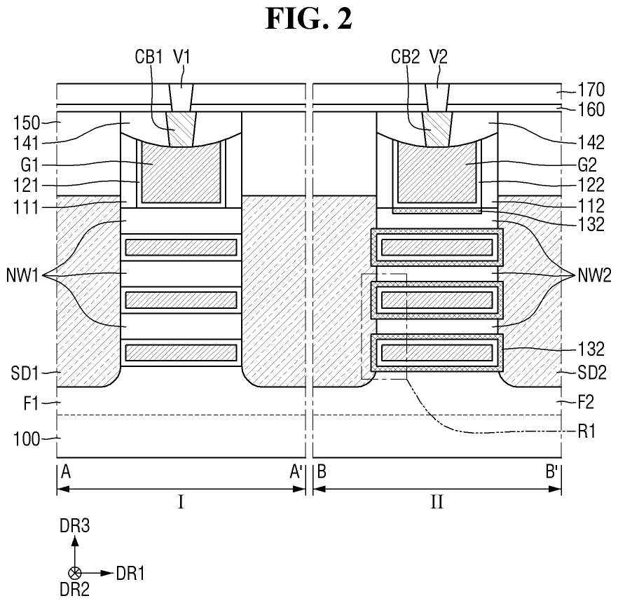

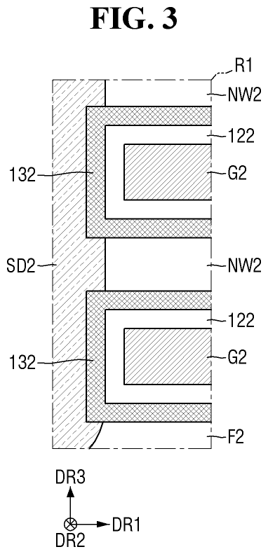

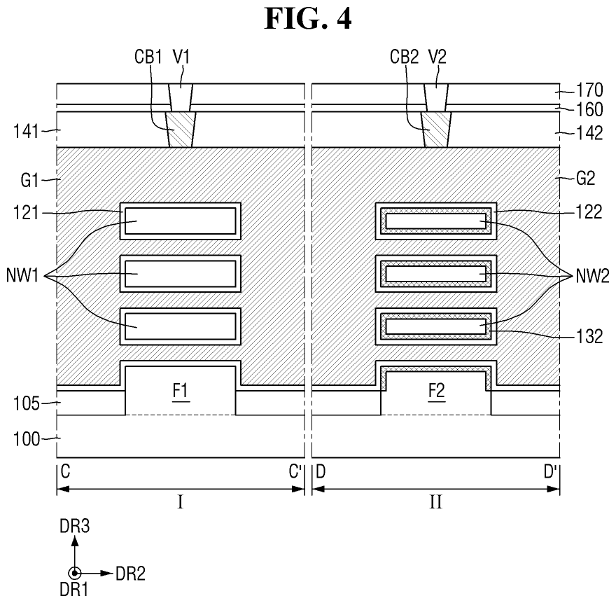

FIG. 1 is a schematic layout view illustrating a semiconductor device according to some embodiments of the present disclosure. FIG. 2 is a cross-sectional view taken along lines A-A′ and B-B′ of FIG. 1. FIG. 3 is an enlarged view illustrating a region RI of FIG. 1. FIG. 4 is a cross-sectional view taken along lines C-C′ and D-D′ of FIG. 1.

Referring to FIGS. 1 to 4, the semiconductor device according to some embodiments of the present disclosure may include a substrate 100, a field insulating layer 105, first and second active patterns F1 and F2, a first plurality and a second plurality of nanosheets NW1 and NW2, first and second gate electrodes G1 and G2, first and second gate spacers 111 and 112, first and second gate insulating layers 121 and 122, a second doping layer 132, first and second capping patterns 141 and 142, first and second source/drain regions SD1 and SD2, a first interlayer insulating layer 150, first and second gate contacts CB1 and CB2, an etch stop layer 160, a second interlayer insulating layer 170, and first and second vias V1 and V2.

The substrate 100 may be a silicon substrate or a silicon-on-insulator (SOI) substrate. Alternatively, the substrate 100 may include silicon germanium, silicon germanium on insulator (SGOI), indium antimonide, lead telluride, indium arsenide, indium phosphide, gallium arsenide or gallium antimonide, but the present disclosure is not limited thereto. An NMOS region I and a PMOS region II may be defined in the substrate 100. For example, an NMOS transistor may be formed on the NMOS region I of the substrate 100. A PMOS transistor may be formed on the PMOS region II of the substrate 100.

Hereinafter, each of a first horizontal direction DR1 and a second horizontal direction DR2 may be defined as a direction parallel with an upper surface of the substrate 100. The second horizontal direction DR2 may be defined as a direction different from the first horizontal direction DR1. A vertical direction DR3 may be defined as a direction perpendicular to each of the first horizontal direction DR1 and the second horizontal direction DR2. That is, the vertical direction DR3 may be defined as a direction perpendicular to the upper surface of the substrate 100.

The first active pattern F1 may be extended in the first horizontal direction DR1 on the NMOS region I of the substrate 100. The second active pattern F2 may be extended on the PMOS region II of the substrate 100 in the first horizontal direction DR1. Each of the first and second active patterns F1 and F2 may protrude from the substrate 100 in the vertical direction DR3. Each of the first and second active patterns F1 and F2 may be a portion of the substrate 100, and may include an epitaxial layer grown from the substrate 100. Each of the first and second active patterns F1 and F2 may include, for example, silicon or germanium, which is an elemental semiconductor material. Additionally or alternatively, each of the first and second active patterns F1 and F2 may include a compound semiconductor, and may include, for example, a Group IV-IV compound semiconductor or a Group III-V compound semiconductor.

The field insulating layer 105 may be on the substrate 100. The field insulating layer 105 may surround sidewalls of each of the first and second active patterns F1 and F2. For example, each of the first and second active patterns F1 and F2 may be more protruded in the vertical direction DR3 than an upper surface of the field insulating layer 105, but the present disclosure is not limited thereto. The field insulating layer 105 may include, for example, a silicon oxide layer, a silicon nitride layer, an oxynitride layer or a combination layer comprising two or more thereof.

The first plurality of nanosheets NW1 may be on the NMOS region I of the substrate 100. The first plurality of nanosheets NW1 may be on the first active pattern F1. The second plurality of nanosheets NW2 may be on the PMOS region II. The second plurality of nanosheets NW2 may be on the second active pattern F2. Each of the first and second plurality of nanosheets NW1 and NW2 may include a plurlality of nanosheets stacked and spaced apart from each other in the vertical direction DR3. Although FIGS. 2 and 4 illustrate that each of the first and second plurality of nanosheets NW1 and NW2 includes three nanosheets stacked to be spaced apart from one another in the vertical direction DR3, this is only for convenience of description and the present disclosure is not limited thereto. For example, in some embodiments, each of the first and second plurality of nanosheets NW1 and NW2 may include four or more nanosheets stacked to be spaced apart from one another in the vertical direction DR3.

For example, each of the first and second plurality of nanosheets NW1 and NW2 may include silicon (Si), but the present disclosure is not limited thereto. In some embodiments, each of the first and second plurality of nanosheets NW1 and NW2 may include silicon germanium (SiGe). In some embodiments, a thickness of each of the first plurality of nanosheets NW1 in the vertical direction DR3 may be greater than that of each of the second plurality of nanosheets NW2 in the vertical direction DR3.

The first gate electrode G1 may be on the NMOS region I of the substrate 100. The first gate electrode G1 may be extended in the second horizontal direction DR2 on the first active pattern F1 and the field insulating layer 105. The first gate electrode G1 may surround the first plurality of nanosheets NW1. The second gate electrode G2 may be on the PMOS region II. The second gate electrode G2 may be extended in the second horizontal direction DR2 on the second active pattern F2 and the field insulating layer 105. The second gate electrode G2 may surround the second plurality of nanosheets NW2.

Each of the first and second gate electrodes G1 and G2 include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), or vanadium (V), or a combination of two or more thereof. Each of the first and second gate electrodes G1 and G2 may include a conductive metal oxide, a conductive metal oxynitride, etc., and may include an oxidized form of the above-described materials.

The first gate spacer 111 may be extended in the second horizontal direction DR2 along both sidewalls of the first gate electrode G1 on an upper surface of the uppermost nanosheet of the first plurality of nanosheets NW1 and the field insulating layer 105. Also, the second gate spacer 112 may be extended in the second horizontal direction DR2 along both sidewalls of the second gate electrode G2 on an upper surface of the uppermost nanosheet of the second plurality of nanosheets NW2 and the field insulating layer 105.

Each of the first and second gate spacers 111 and 112 may include at least one of, for example, silicon nitride (SiN), silicon oxynitride (SiON), silicon oxide (SiO₂), silicon oxycarbonitride (SiOCN), silicon boron nitride (SiBN), silicon oxyboron nitride (SiOBN), or silicon oxycarbide (SiOC) or a combination of two or more thereof, but the present disclosure is not limited thereto.

The first gate insulating layer 121 may be between the first gate electrode G1 and the first gate spacer 111. The first gate insulating layer 121 may be on both sidewalls of the first gate electrode G1 in the first horizontal direction DR1. The first gate insulating layer 121 may be between the first gate electrode G1 and the first active pattern F1. The first gate insulating layer 121 may be between the first gate electrode G1 and the fielding insulating layer 105. The first gate insulating layer 121 may be between the first gate electrode G1 and the first plurality of nanosheets NW1.

The second gate insulating layer 122 may be between the second gate electrode G2 and the second gate spacer 112. The second gate insulating layer 122 may be on both sidewalls of the second gate electrode G2 in the first horizontal direction DR1. The second gate insulating layer 122 may be between the second gate electrode G2 and the second active pattern F2. The second gate insulating layer 122 may be between the second gate electrode G2 and the field insulating layer 105. The second gate insulating layer 122 may be between the second gate electrode G2 and the second plurality of nanosheets NW2.

Each of the first and second gate insulating layers 121 and 122 may include at least one of silicon oxide, silicon oxynitride, silicon nitride, or a high dielectric constant material having a dielectric constant greater than that of the silicon oxide. The high dielectric constant material may include one or more of, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some other embodiments may include a negative capacitance (NC) FET based on a negative capacitor. For example, each of the first and second gate insulating layers 121 and 122 may include a ferroelectric material layer having ferroelectric characteristics and a paraelectric material layer having paraelectric characteristics.

The ferroelectric material layer may have a negative capacitance, and the paraelectric material layer may have a positive capacitance. For example, when two or more capacitors are connected in series and the capacitance of each capacitor has a positive value, the total capacitance is more reduced than (e.g., less than) the capacitance of each individual capacitor. On the other hand, when at least one of capacitances of two or more capacitors connected in series has a negative value, the total capacitance may have a positive value and may be greater than an absolute value of each individual capacitance.

When the ferroelectric material layer having a negative capacitance and the paraelectric material layer having a positive capacitance are connected in series, the total capacitance value of the ferroelectric material layer and the paraelectric material layer, which are connected in series, may be increased. Based on the total capacitance value that is increased, a transistor having the ferroelectric material layer may have a subthreshold swing (SS) less than 60 mV/decade at a room temperature.

The ferroelectric material layer may have ferroelectric characteristics. The ferroelectric material layer may include at least one of, for example, hafnium oxide, hafnium zirconium oxide, barium strontium titanium oxide, barium titanium oxide, or lead zirconium titanium oxide. For example, the hafnium zirconium oxide may be a material doped with zirconium (Zr) in hafnium oxide. For another example, the hafnium zirconium oxide may be a compound of hafnium (Hf), zirconium (Zr) and oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). A type of the dopant included in the ferroelectric material layer may be varied depending on the ferroelectric material of the ferroelectric material layer.

When the ferroelectric material layer includes hafnium oxide, the dopant included in the ferroelectric material layer may include at least one of gadolinium (Gd), silicon (Si), zirconium (Zr), aluminum (Al), or yttrium (Y).

When the dopant is aluminum (Al), the ferroelectric material layer may include aluminum of 3 atomic % (at%) to 8 at %. In this case, a ratio of the dopant may be a ratio of aluminum to a sum of hafnium and aluminum.

When the dopant is silicon (Si), the ferroelectric material layer may include silicon of 2 at % to 10 at %. When the dopant is yttrium (Y), the ferroelectric material layer may include yttrium of 2 at % to 10 at %. When the dopant is gadolinium (Gd), the ferroelectric material layer may include gadolinium of 1 at % to 7 at %. When the dopant is zirconium (Zr), the ferroelectric material layer may include zirconium of 50 at % to 80 at %.

The paraelectric material layer may have paraelectric characteristics. The paraelectric material layer may include at least one of, for example, silicon oxide or metal oxide having a high dielectric constant. The metal oxide included in the paraelectric material layer may include at least one of, for example, hafnium oxide, zirconium oxide, or aluminum oxide, but the present disclosure is not limited thereto.

The ferroelectric material layer and the paraelectric material layer may include the same material. Although the ferroelectric material layer has ferroelectric characteristics, the paraelectric material layer may not have ferroelectric characteristics. For example, when the ferroelectric material layer and the paraelectric material layer include hafnium oxide, a crystal structure of hafnium oxide included in the ferroelectric material layer is different from that of hafnium oxide included in the paraelectric material layer.

The ferroelectric material layer may have a thickness having ferroelectric characteristics. The thickness of the ferroelectric material layer may be, for example, 0.5 nm to 10 nm, but the present disclosure is not limited thereto. Since a threshold thickness indicating ferroelectric characteristics may be varied depending on each ferroelectric material, the thickness of the ferroelectric material layer may be varied depending on the ferroelectric material.

For example, each of the first and second gate insulating layers 121 and 122 may include one ferroelectric material layer. For another example, each of the first and second gate insulating layers 121 and 122 may include a plurality of ferroelectric material layers spaced apart from each other. The first and second gate insulating layers 121 and 122 may have a stacked layer structure in which a plurality of ferroelectric material layers and a plurality of paraelectric material layers are alternately stacked.

The first capping pattern 141 may be extended in the second horizontal direction DR2 on each of the first gate electrode G1, the first gate insulating layer 121 and the first gate spacer 111. The second capping pattern 142 may be extended in the second horizontal direction DR2 on each of the second gate electrode G2, the second gate insulating layer 122 and the second gate spacer 112. For example, the first capping pattern 141 may be in contact with an upper surface of the first gate spacer 111. Also, the second capping pattern 142 may be in contact with an upper surface of the second gate spacer 112, but the present disclosure is not limited thereto. In some embodiments, the first capping pattern 141 may be between the first gate spacers 111. Also, the second capping pattern 142 may be between the second gate spacers 112. In some embodiments, an upper surface of the first gate spacers 111 may be above an upper surface of the first capping pattern 141 and/or an upper surface of the second gate spacers 112 may be above an upper surface of the second capping pattern 142.

Each of the first and second capping patterns 141 and 142 may include at least one of, for example, silicon nitride (SiN), silicon oxynitride (SiON), silicon oxide (SiO₂), silicon carbonitride (SiCN), silicon oxycarbonitride (SiOCN) or their combination, but the present disclosure is not limited thereto.

The first source/drain region SD1 may be on both sides of the first gate electrode G1 in the first horizontal direction DR1 on the first active pattern F1. The first source/drain region SD1 may be on both sides of the first plurality of nanosheets NW1 in the first horizontal direction DR1 on the first active pattern F1. For example, the first source/drain region SD1 may be in contact with both sidewalls of the first plurality of nanosheets NW1 in the first horizontal direction DR1. For example, the first source/drain region SD1 may be in contact with the first gate insulating layer 121.

The second source/drain region SD2 may be on both sides of the second gate electrode G2 in the first horizontal direction DR1 on the second active pattern F2. The second source/drain region SD2 may be on both sides of the second plurality of nanosheets NW2 in the first horizontal direction DR1 on the second active pattern F2. For example, the second source/drain region SD2 may be in contact with both sidewalls of the second plurality of nanosheets NW2 in the first horizontal direction DR1. For example, the second source/drain region SD2 is not in contact with the second gate insulating layer 122.

The second doping layer 132 may be between the second gate insulating layer 122 and the second active pattern F2. The second doping layer 132 may be between the second gate insulating layer 122 and the second plurality of nanosheets NW2. The second doping layer 132 may be between the second gate insulating layer 122 and the second source/drain region SD2. For example, the second doping layer 132 may be in contact with each of the second gate insulating layer 122, the second active pattern F2, the second plurality of nanosheets NW2 and the second source/drain region SD2.

As seen in FIG. 3, in a cross-sectional view taken along the first horizontal direction DR1, at least a portion of the second doping layer 132 may be between the second source/drain region SD2 and the second gate insulating layer 122. For example, between the second source/drain region SD2 and the second gate insulating layer 122, the second doping layer 132 may be in contact with the second source/drain region SD2. For example, the second doping layer 132 may not be between (may be absent from between) the second source/drain region SD2 and the second plurality of nanosheets NW2. In some embodiments, the second source/drain region SD2 may directly contact the second plurality of nanosheets NW2 without the second doping layer 132 therebetween. For example, at least a portion of the second doping layer 132 may be more protruded in the first horizontal direction DR1 toward the second source/drain region SD2 than the sidewalls of the second plurality of nanosheets NW2.

For example, and as seen in FIG. 1, at least a portion of the second doping layer 132 may overlap the uppermost nanosheet of the second plurality of nanosheets NW2 in the first horizontal direction DR1. For example, at least a portion of the sidewall of the second doping layer 132 in the first horizontal direction DR1 may be in contact with the uppermost nanosheet of the second plurality of nanosheets NW2. For example, the uppermost surface of the second doping layer 132 may be formed on the same plane as the upper surface of the uppermost nanosheet of the second plurality of nanosheets NW2, but the present disclosure are not limited thereto.

As seen in FIG. 4, in the cross-sectional view taken along the second horizontal direction DR2, the second doping layer 132 may be along sidewalls and an upper surface of the second active pattern F2 that is protruded in the vertical direction DR3 on the upper surface of the field insulating layer 105. For example, a first width of the second active pattern F2 in the second horizontal direction DR2, which is surrounded by the second doping layer 132, may be smaller than a second width of the second active pattern F2 in the second horizontal direction DR2, which is surrounded by the field insulating layer 105. For example, the lowermost surface of the second doping layer 132 may be in contact with an upper surface of a portion of the second active pattern F2, which is surrounded by the field insulating layer 105. The second doping layer 132 may surround sidewalls, a lower surface and an upper surface of each of the second plurality of nanosheets NW2 in the second horizontal direction DR2.

The second doping layer 132 may have a liner shape. For example, a thickness of the second doping layer 132 may be in the range of 2 Å to 15 Å. The second doping layer 132 may include, for example, silicon (Si) or silicon germanium (SiGe). For example, the second doping layer 132 may be doped with a first doping material that is an n-type doping material. That is, the second doping layer 132 on a surface of the second plurality of nanosheets NW2 on the PMOS region II of the substrate 100 may include silicon (Si) or silicon germanium (SiGe), which is doped with an n-type doping material. For example, the n-type doping material may include at least one of phosphorus (P), arsenic (As) or antimony (Sb).

The first interlayer insulating layer 150 may be on the field insulating layer 105. Although the first interlayer insulating layer 150 is shown in FIG. 4 as being in contact with the upper surface of the field insulating layer 105, the present disclosure is not limited thereto. In some other embodiments, an etch stop layer may be between the upper surface of the field insulating layer 105 and the first interlayer insulating layer 150. The first interlayer insulating layer 150 may cover each of the first and second source/drain regions SD1 and SD2. The first interlayer insulating layer 150 may surround sidewalls of each of the first and second gate spacers 111 and 112 and the first and second capping patterns 141 and 142. For example, an upper surface of the first interlayer insulating layer 150 may be formed on the same plane as an upper surface of each of the first and second capping patterns 141 and 142, but the present disclosure is not limited thereto. In some other embodiments, the first interlayer insulating layer 150 may cover the upper surface of each of the first and second capping patterns 141 and 142.

The first interlayer insulating layer 150 may include at least one of, for example, silicon oxide, silicon nitride, silicon oxynitride or a low dielectric constant material. The low dielectric constant material may include Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), Tonen SilaZen (TOSZ), Fluoride Silicate Glass (FSG), polyimide nanofoams such as polypropylene oxide, Carbon Doped silicon Oxide (CDO), Organo Silicate Glass (OSG), SILK, Amorphous Fluorinated Carbon, silica aerogels, silica xerogels, mesoporous silica or their combination, but the present disclosure is not limited thereto.

The first gate contact CB1 may be connected to the first gate contact G1 by passing through the first capping pattern 141 in the vertical direction DR3. The second gate contact CB2 may be connected to the second gate contact G2 by passing through the second capping pattern 142 in the vertical direction DR3. For example, an upper surface of each of the first and second gate contacts CB1 and CB2 may be formed on the same plane as the upper surface of each of the first and second capping patterns 141 and 142.

In FIGS. 2 and 4, each of the first and second gate contacts CB1 and CB2 is shown as being formed of a single layer, but the present disclosure is not limited thereto. In some other embodiments, each of the first and second gate contacts CB1 and CB2 may be formed of a multi-layer. Each of the first and second gate contacts CB1 and CB2 may include a conductive material. Each of the first and second gate contacts CB1 and CB2 may include at least one of, for example, tantalum (Ta), tantalum nitride (TaN), titanium (Ti), titanium nitride (TiN), ruthenium (Ru), cobalt (Co), nickel (Ni), nickel boron (NiB), tungsten (W), tungsten nitride (WN), zirconium (Zr), zirconium nitride (ZrN), vanadium (V), vanadium nitride (VN), niobium (Nb), niobium nitride (NbN), platinum (Pt), iridium (Rh), rhodium (Rh), aluminum (Al), copper (Cu), or molybdenum (Mo).

The etch stop layer 160 may be on the upper surface of each of the first interlayer insulating layer 150, the first and second capping patterns 141 and 142 and the first and second gate contacts CB1 and CB2. Although the etch stop layer 160 is shown in FIGS. 2 to 4 as being formed as a single layer, the present disclosure is not limited thereto. In some other embodiments, the etch stop layer 160 may be formed of a multi-layer. The etch stop layer 160 may include at least one of, for example, aluminum oxide, aluminum nitride, hafnium oxide, zirconium oxide, silicon oxide, silicon nitride, silicon oxynitride, or a low dielectric constant material. The second interlayer insulating layer 170 may be on the etch stop layer 160. The second interlayer insulating layer 170 may include at least one of, for example, silicon oxide, silicon nitride, silicon oxynitride, or a low dielectric constant material.

The first via V1 may be connected to the first gate contact CB1 by passing through the second interlayer insulating layer 170 and the etch stop layer 160 in the vertical direction DR3. The second via V2 may be connected to the second gate contact CB2 by passing through the second interlayer insulating layer 170 and the etch stop layer 160 in the vertical direction DR3. Although each of the first via V1 and the second via V2 is shown in FIGS. 2 and 4 as being formed of a single layer, the present disclosure is not limited thereto. That is, each of the first via V1 and the second via V2 may be formed of a multi-layer. Each of the first via V1 and the second via V2 may include a conductive material.

In the semiconductor device according to some embodiments of the present disclosure, the second doping layer 132 on the surface of the second plurality of nanosheets NW2 on the PMOS region II of the substrate 100 may include silicon (Si) or silicon germanium (SiGe), which may be doped with an n-type doping material. In other words, the second doping layer 132 including silicon (Si) or silicon germanium (SiGe), which is doped with an n-type doping material, may be on the surface of the second plurality of nanosheets NW2 corresponding to a channel region of the PMOS transistor on the PMOS region II of the substrate 100. Therefore, the semiconductor device according to some embodiments of the present disclosure may control (e.g., may control effectively) a threshold voltage of the PMOS transistor.

Hereinafter, a method for fabricating a semiconductor device according to some embodiments of the present disclosure will be described with reference to FIGS. 2 to 25.

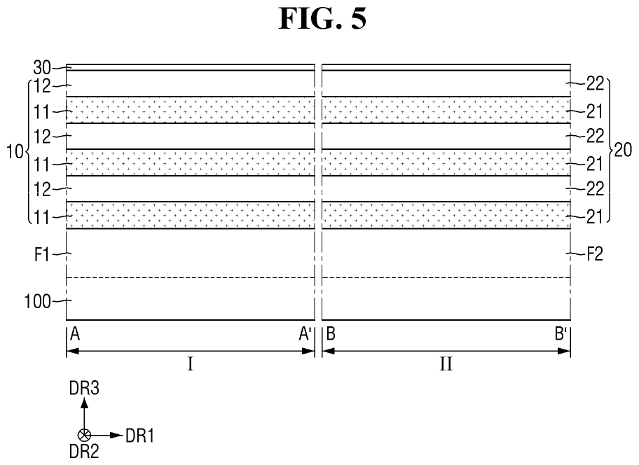

FIGS. 5 to 25 are views illustrating intermediate steps to describe a method for fabricating a semiconductor device according to some embodiments of the present disclosure.

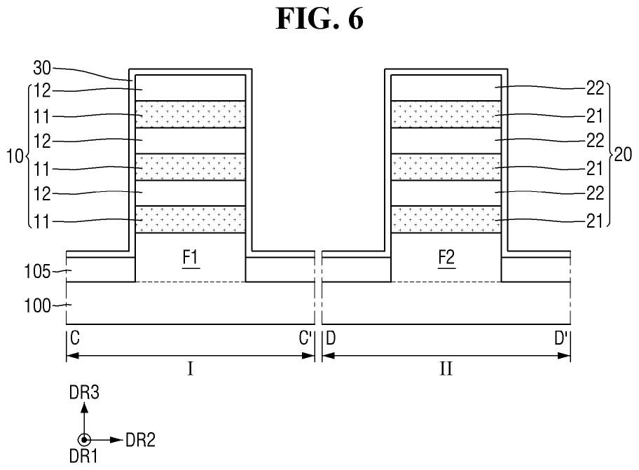

Referring to FIGS. 5 and 6, a first stack structure 10 may be formed on the NMOS region I of the substrate 100. In addition, a second stack structure 20 may be formed on the PMOS region II of the substrate 100. For example, the first stack structure 10 and the second stack structure 20 may be formed through the same process.

The first stack structure 10 may include a first sacrificial layer 11 and a first semiconductor layer 12, which may be alternately stacked on the substrate 100. For example, the first sacrificial layer 11 may be formed on the lowermost portion of the first stack structure 10, and the first semiconductor layer 12 may be formed on the uppermost portion of the first stack structure 10. The second stack structure 20 may include a second sacrificial layer 21 and a second semiconductor layer 22, which may be alternately stacked on the substrate 100. For example, the second sacrificial layer 21 may be formed on the lowermost portion of the second stack structure 20, and the second semiconductor layer 22 may be formed on the uppermost portion of the second stack structure 20, but the present disclosure is not limited thereto. In some other embodiments, the first sacrificial layer 11 may be formed on the uppermost portion of the first stack structure 10. The second sacrificial layer 21 may be formed on the uppermost portion of the second stack structure 20. Each of the first sacrificial layer 11 and the second sacrificial layer 21 may include, for example, silicon germanium (SiGe). Each of the first semiconductor layer 12 and the second semiconductor layer 22 may include, for example, silicon (Si).

A portion of the first stack structure 10 and a portion of the second stack structure 20 may be etched. A portion of the substrate 100 may be also etched while a portion of the first stack structure 10 and a portion of the second stack structure 20 are being etched. The first active pattern F1 may be defined below the first stack structure 10 on the NMOS region I of the substrate 100 through the etching process. The second active pattern F2 may be defined below the second stack structure 20 on the PMOS region II of the substrate 100. Each of the first active pattern F1 and the second active pattern F2 may be extended in the first horizontal direction DR1.

Subsequently, the field insulating layer 105 may be formed on the upper surface of the substrate 100. The field insulating layer 105 may surround sidewalls of each of the first active pattern F1 and the second active pattern F2. For example, the upper surface of each of the first active pattern F1 and the second active pattern F2 may be higher than that of the field insulating layer 105. A pad oxide layer 30 may be formed to cover the upper surface of the field insulating layer 105, the exposed sidewalls of each of the first and second active patterns F1 and F2, and sidewalls and an upper surface of each of the first and second stack structures 10 and 20. For example, the pad oxide layer 30 may be formed to conform to the shape of the first and second stack structures 10 and 20. The pad oxide layer 30 may include, for example, silicon oxide (SiO₂).

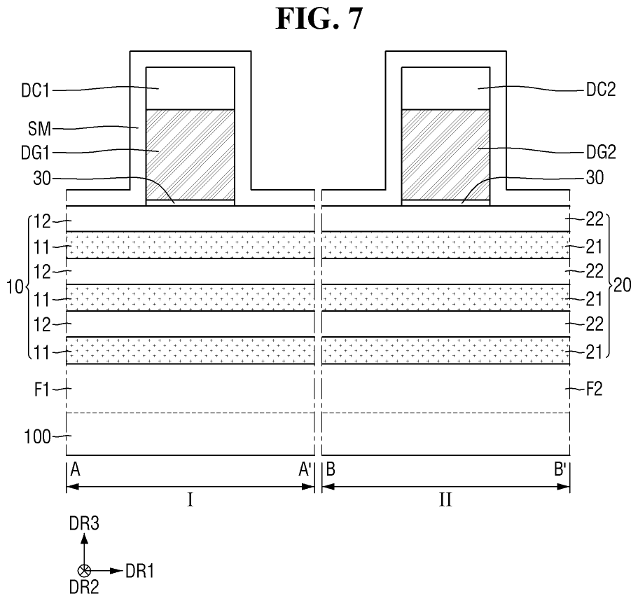

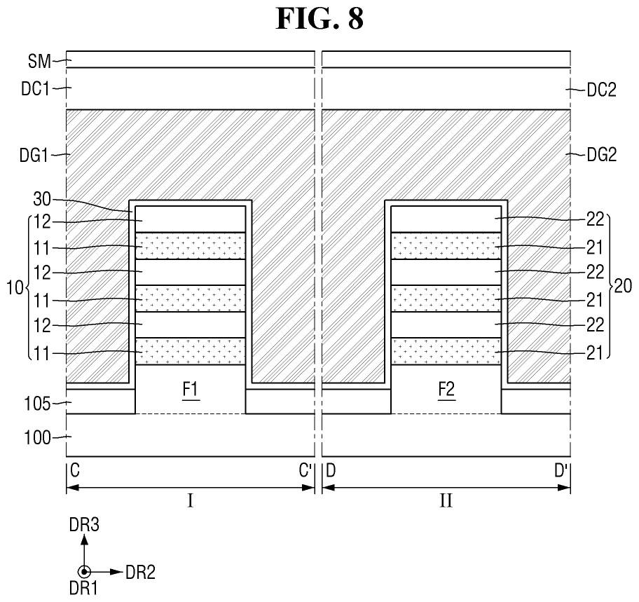

Referring to FIGS. 7 and 8, a first dummy gate DG1 and a first dummy capping pattern DC1, which are extended in the second horizontal direction DR2 on the pad oxide layer 30, may be formed on the first stack structure 10 and the field insulating layer 105. A second dummy gate DG2 and a second dummy capping pattern DC2, which are extended in the second horizontal direction DR2 on the pad oxide layer 30, may be formed on the second stack structure 20 and the field insulating layer 105. The first dummy capping pattern DC1 may be on the first dummy gate DG1. The second dummy capping pattern DC2 may be on the second dummy gate DG2. While the first and second dummy gates DG1 and DG2 and the first and second dummy capping patterns DC1 and DC2 are being formed, the remaining pad oxide layer 30 except for a portion overlapped with each of the first and second dummy gates DG1 and DG2 in the vertical direction DR3 on the substrate 100 may be removed.

Subsequently, a spacer material layer SM may be formed to cover sidewalls of each of the first and second dummy gates DG1 and DG2, sidewalls and an upper surface of each of the first and second dummy capping patterns DC1 and DC2, sidewalls and an upper surface of each of the first and second stack structures 10 and 20 and an upper surface of the field insulating layer 105. For example, the spacer material layer SM may be formed to conform to the shape of the first and second stack structures 10 and 20. The spacer material layer SM may include at least one of, for example, silicon nitride (SiN), silicon oxycarbonitride (SiOCN), silicon boron carbonitride (SiBCN), silicon carbonitride (SiCN), or silicon oxynitride (SiON) or a combination of two or more thereof.

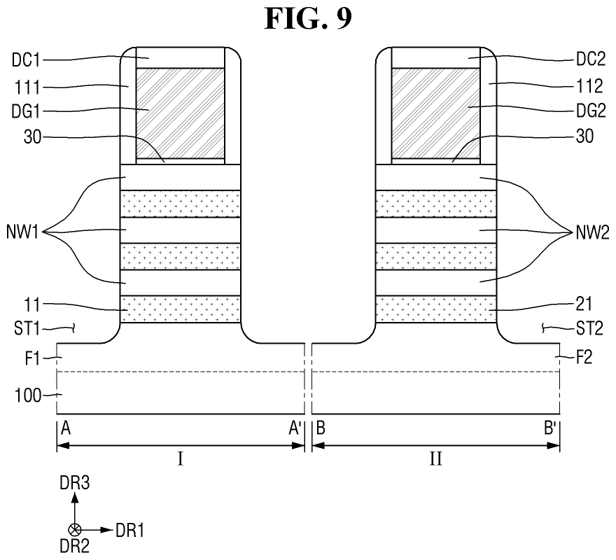

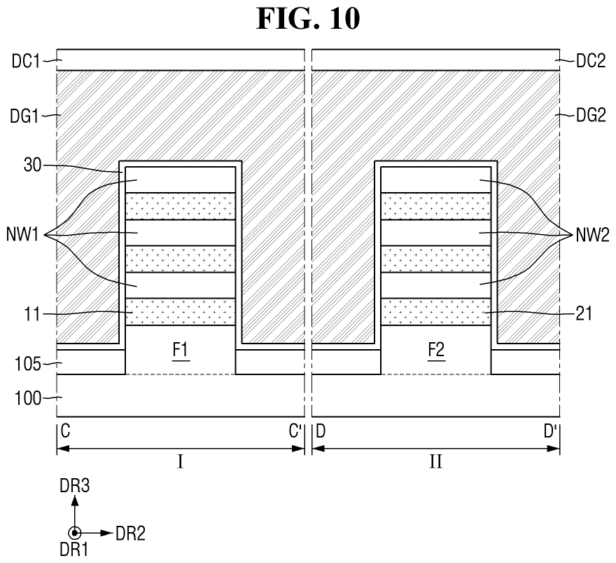

Referring to FIGS. 9 and 10, the first stack structure (10 of FIGS. 7 and 8) may be etched using the first dummy gate DG1 and the first dummy capping pattern DC1 as masks to form a first source/drain trench ST1. The second stack structure (20 of FIGS. 7 and 8) may be etched using the second dummy gate DG2 and the second dummy capping pattern DC2 as masks to form a second source/drain trench ST2. For example, the first source/drain trench ST1 may be extended into the first active pattern F1. The second source/drain trench ST2 may be extended into the second active pattern F2.

For example, while the first source/drain trench ST1 is being formed, a portion of each of the first dummy capping pattern DC1 and the spacer material layer (SM of FIGS. 7 and 8) formed on the first dummy capping pattern DC1 may be etched. While the second source/drain trench ST2 is being formed, a portion of each of the second dummy capping pattern DC2 and the spacer material layer (SM of FIGS. 7 and 8) formed on the upper surface of the second dummy capping pattern DC2 may be etched. For example, the spacer material layer (SM of FIGS. 7 and 8) remaining on the sidewalls of each of the first dummy capping pattern DC1 and the first dummy gate DG1 may be defined as the first gate spacer 111. In addition, the spacer material layer (SM of FIGS. 7 and 8) remaining on the sidewalls of each of the second dummy capping pattern DC2 and the second dummy gate DG2 may be defined as the second gate spacer 112.

For example, after the first source/drain trench STI is formed, the first semiconductor layer (12 of FIGS. 7 and 8) remaining below the first dummy gate DG1 on the first active pattern F1 may be defined as the first plurality of nanosheets NW1. In addition, after the second source/drain trench ST2 is formed, the second semiconductor layer (22 of FIGS. 7 and 8) remaining below the second dummy gate DG2 on the second active pattern F2 may be defined as the second plurality of nanosheets NW2.

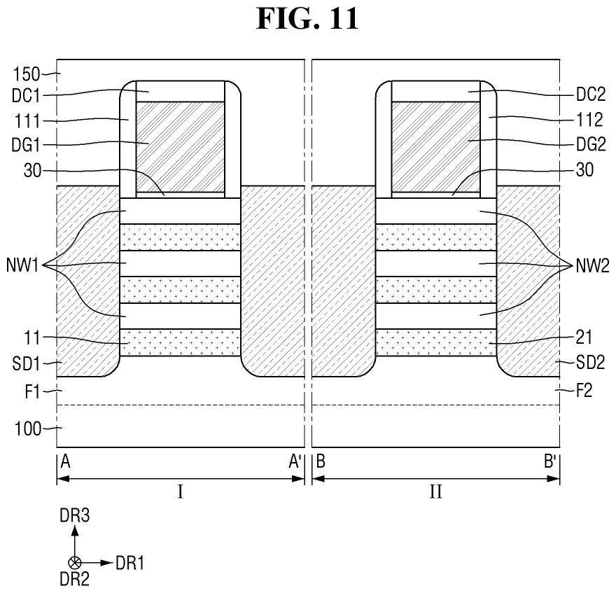

Referring to FIG. 11, the first source/drain region SD1 may be formed in the first source/drain trench ST1 formed on the first active pattern F1. The second source/drain region SD2 may be formed in the second source/drain trench ST2 formed on the second active pattern F2. Subsequently, the first interlayer insulating layer 150 may be formed to cover sidewalls and an upper surface of each of the first and second source/drain regions SD1 and SD2, the first and second gate spacers 111 and 112 and the first and second dummy capping patterns DC1 and DC2, respectively.

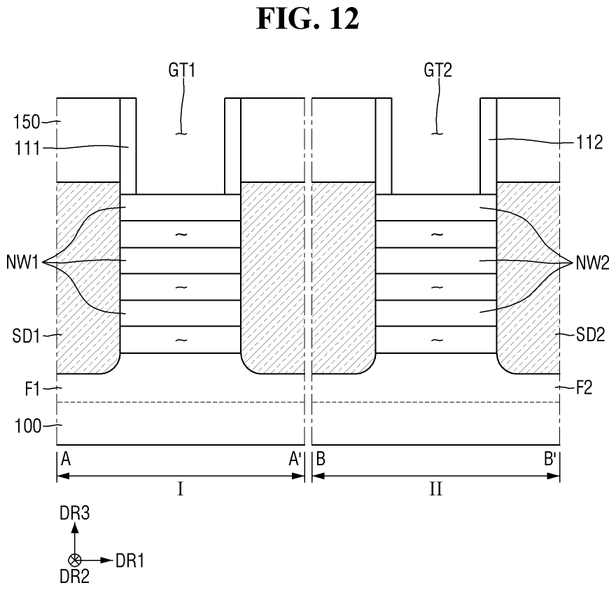

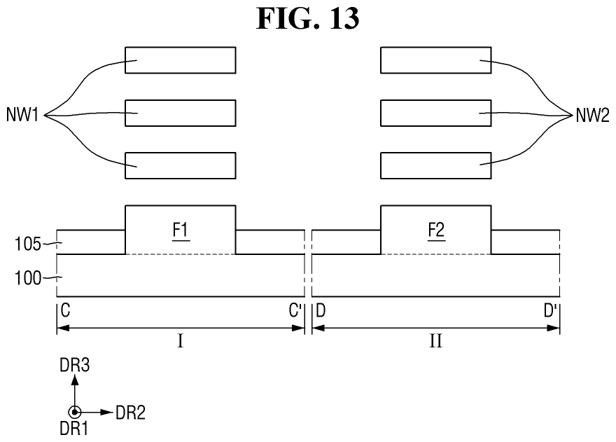

Referring to FIGS. 12 and 13, the upper surface of each of the first and second dummy gates (e.g., DG1 and DG2 of FIG. 11) may be exposed through a planarization process. Then, the first and second dummy gates (DG1 and DG2 of FIG. 11), the pad oxide layer (30 of FIG. 11) and the first and second sacrificial layers (11 and 21 of FIG. 11) may be respectively removed. The portion from which the first dummy gate (DG1 of FIG. 11) is removed may be defined as a first gate trench GT1. The portion from which the second dummy gate (DG2 of FIG. 11) is removed may be defined as a second gate trench GT2.

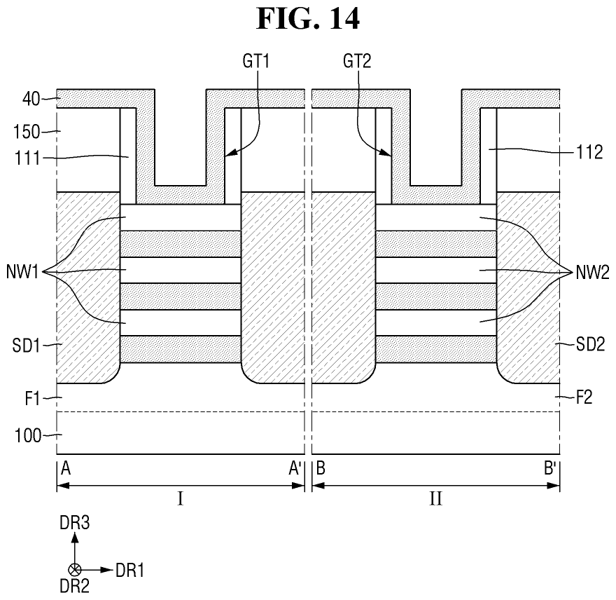

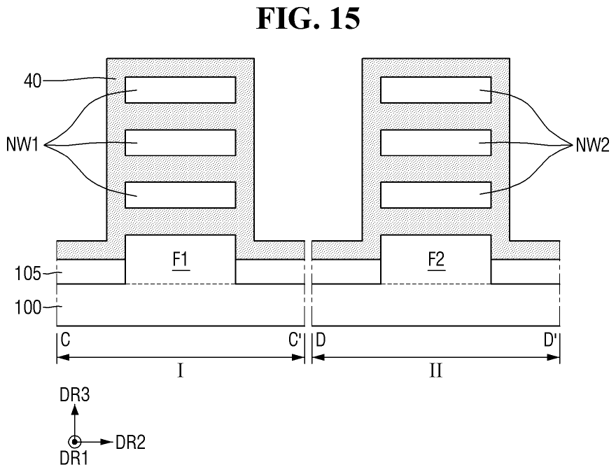

Referring to FIGS. 14 and 15, a liner layer 40 may be formed along sidewalls and a bottom surface of each of the first gate trench GT1 and the second gate trench GT2. The liner layer 40 may be formed along the exposed surface of each of the first and second plurality of nanosheets NW1 and NW2. For example, the liner layer 40 may fill a portion from which each of the first and second sacrificial layers (11 and 21 of FIG. 11) is removed. The liner layer 40 may be formed on the upper surface of the field insulating layer 105, the upper surface of each of the first and second gate spacers 111 and 112 and the upper surface of the first interlayer insulating layer 150.

The liner layer 40 may include a material having an etch selectivity with each of the first and second plurality of nanosheets NW1 and NW2, the first and second active patterns F1 and F2, the field insulating layer 105, the first interlayer insulating layer 150 and the first and second gate spacers 111 and 112.

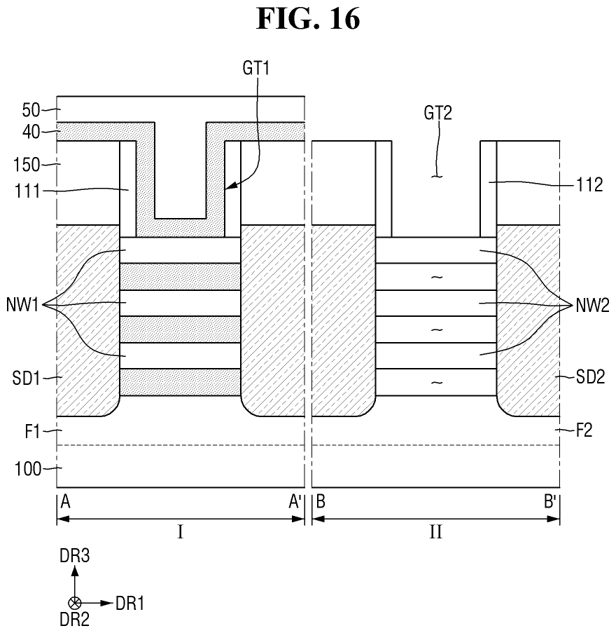

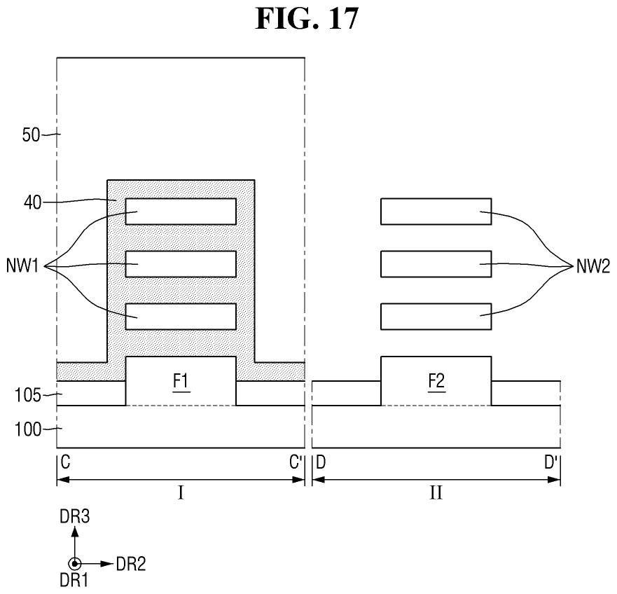

Referring to FIGS. 16 and 17, a mask pattern 50 may be formed to cover the liner layer 40 on the NMOS region I of the substrate 100. Subsequently, the liner layer 40 formed on the PMOS region II of the substrate 100 may be etched.

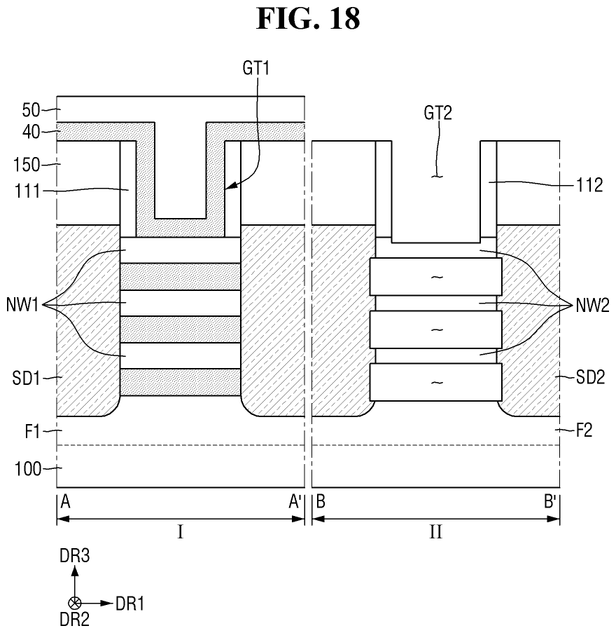

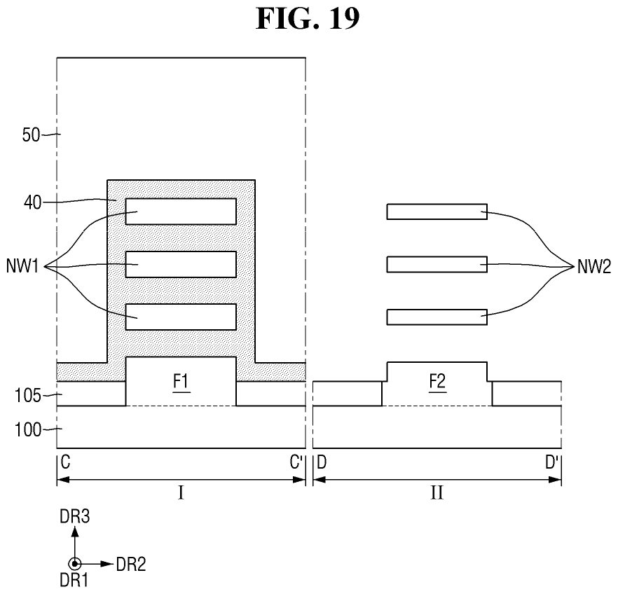

Referring to FIGS. 18 and 19, a portion of the exposed surface of the second plurality of nanosheets NW2, a portion of the exposed surface of the second source/drain region SD2 and a portion of the exposed surface of the second active pattern F2 may be etched through the second gate trench GT2. Therefore, a thickness of each of the second plurality of nanosheets NW2 in the vertical direction DR3 may be smaller than that of each of the first plurality of nanosheets NW1 in the vertical direction DR3. A first width of a portion of the second active pattern F2 in the second horizontal direction DR2, which is protruded in the vertical direction DR3 on the upper surface of the field insulating layer 105, may be smaller than a second width of the remaining portion of the second active pattern F2 in the second horizontal direction DR2, which is surrounded by the field insulating layer 105.

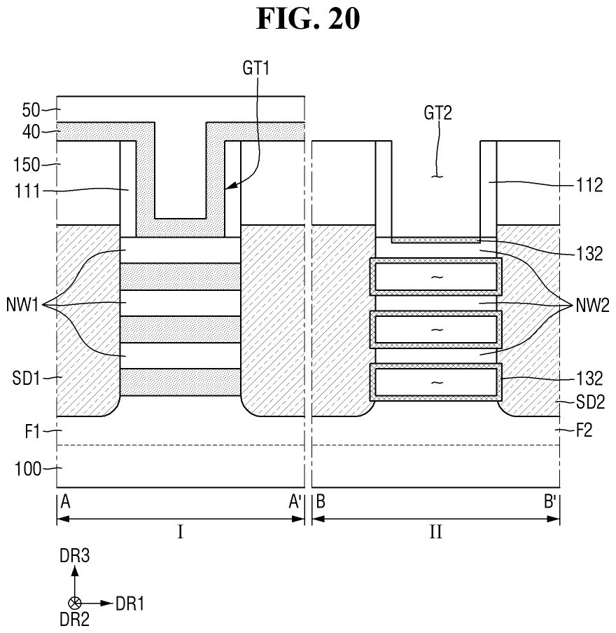

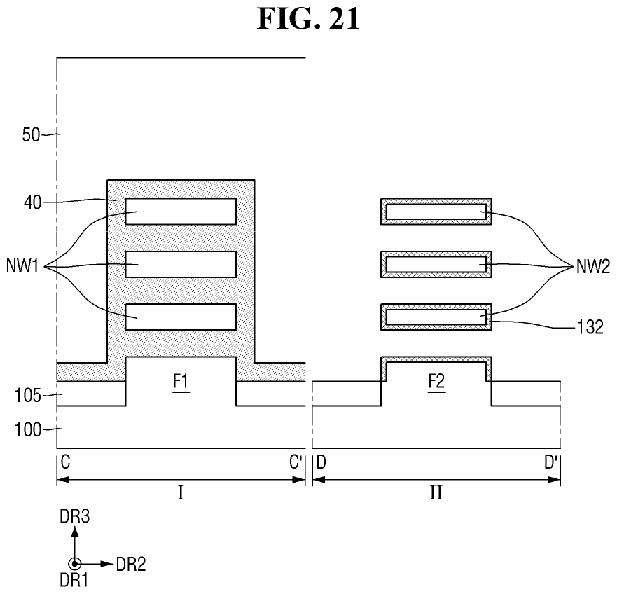

Referring to FIGS. 20 and 21, the second doping layer 132 may be formed on each of the etched portion of the second plurality of nanosheets NW2, the etched portion of the second source/drain region SD2 and the etched portion of the second active pattern F2. That is, the etched portion of the second plurality of nanosheets NW2, the etched portion of the second source/drain region SD2 and the etched portion of the second active pattern F2 may be replaced with the second doping layer 132. For example, the second doping layer 132 may be formed by being epitaxially grown from each of the second plurality of nanosheets NW2, the second source/drain region SD2 and the second active pattern F2.

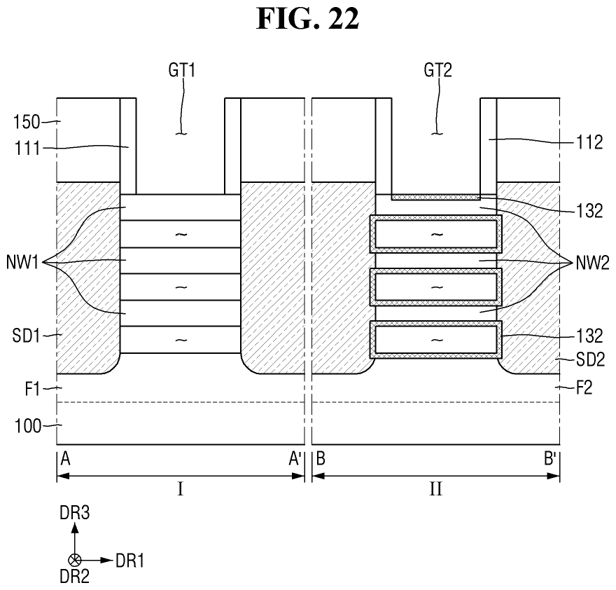

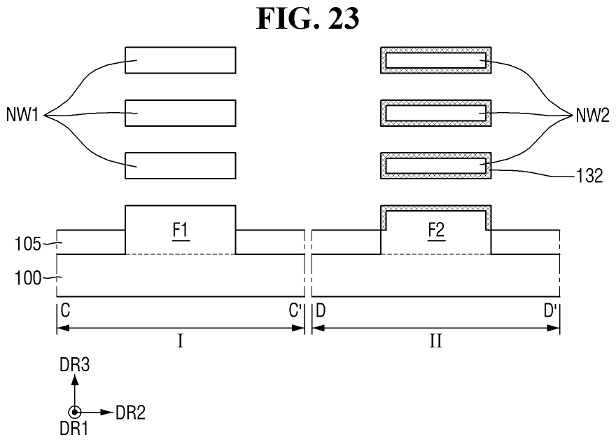

Referring to FIGS. 22 and 23, the mask pattern 50 and the liner layer 40, which are formed on the NMOS region I of the substrate 100, may be sequentially removed.

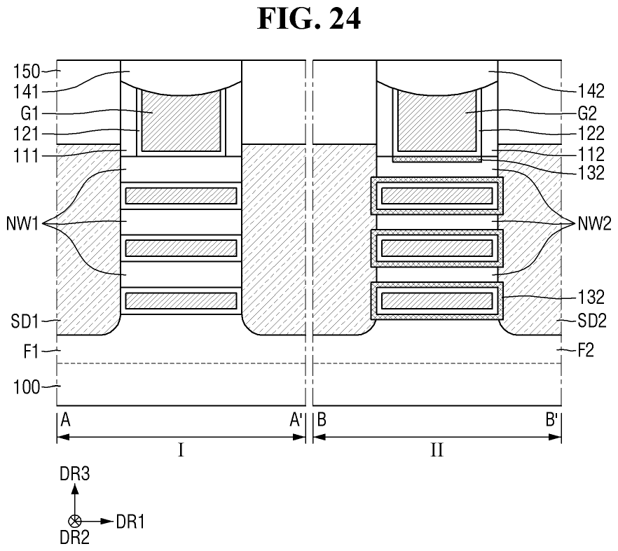

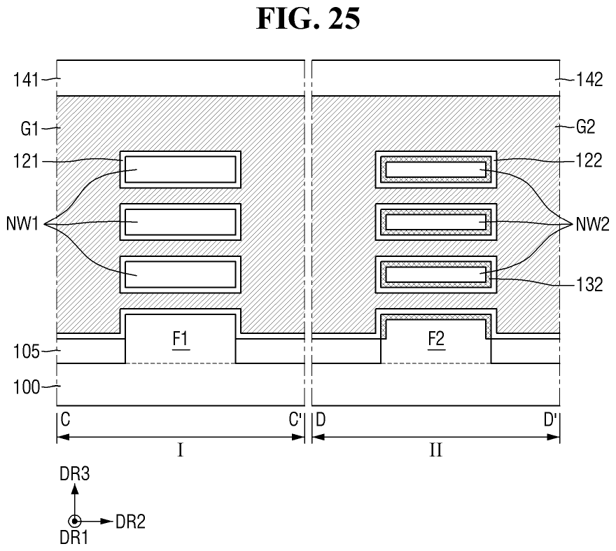

Referring to FIGS. 24 and 25, the first gate insulating layer 121, the first gate electrode G1 and the first capping pattern 141 may be sequentially formed in a portion from which the first sacrificial layer (11 of FIG. 11) is removed and inside the first gate trench (GT1 of FIG. 22). The second gate insulating layer 122, the second gate electrode G2 and the second capping pattern 142 may be sequentially formed in a portion from which the second sacrificial layer (21 of FIG. 11) is removed and inside the second gate trench (GT2 of FIG. 22).

Referring to FIGS. 2 to 4, the first gate contact CB1 connected to the first gate electrode G1 may be formed by passing through the first capping pattern 141 in the vertical direction DR3. The second gate contact CB2 connected to the second gate electrode G2 may be formed by passing through the second capping pattern 142 in the vertical direction DR3. The etch stop layer 160 and the second interlayer insulating layer 170 may be sequentially formed on the upper surface of each of the first interlayer insulating layer 150, the first and second capping patterns 141 and 142 and the first and second gate contacts CB1 and CB2.

Subsequently, the first via VI connected to the first gate contact CB1 may be formed by passing through the etch stop layer 160 and the second interlayer insulating layer 170 in the vertical direction DR3. Also, the second via V2 connected to the second gate contact CB2 may be formed by passing through the etch stop layer 160 and the second interlayer insulating layer 170 in the vertical direction DR3. Through this fabricating process, the semiconductor device shown in FIGS. 2 to 4 may be fabricated.

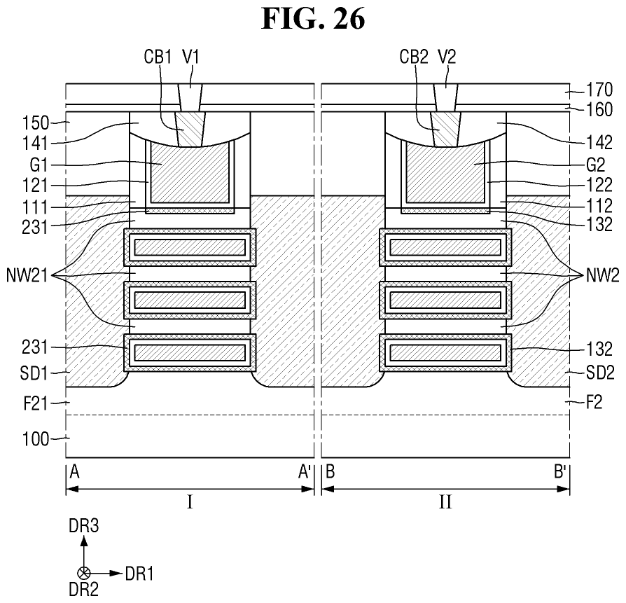

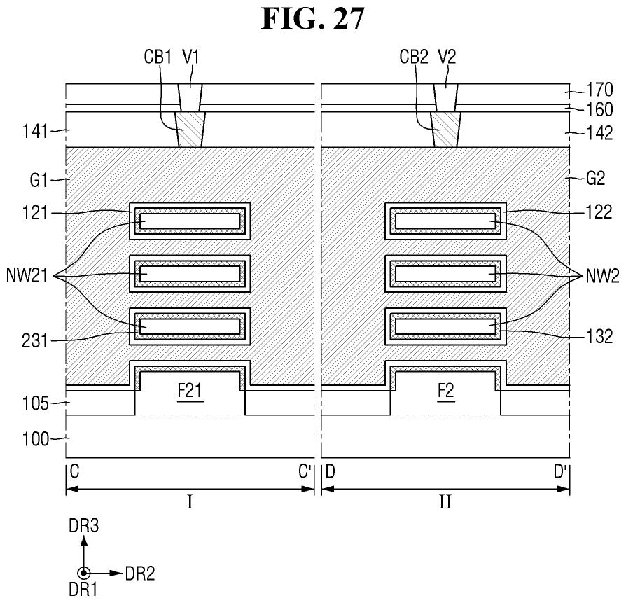

Hereinafter, a semiconductor device according to some other embodiments of the present disclosure will be described with reference to FIGS. 26 and 27. The following description will be based on differences from the semiconductor device shown in FIGS. 1 to 4.

FIGS. 26 and 27 are cross-sectional views illustrating a semiconductor device according to some embodiments of the present disclosure.

Referring to FIGS. 26 and 27, in the semiconductor device according to some embodiments of the present disclosure, a first doping layer 231 may be on the NMOS region I of the substrate 100.

For example, the first doping layer 231 may be between the first gate insulating layer 121 and the first active pattern F21. The first doping layer 231 may be between the first gate insulating layer 121 and the first plurality of nanosheets NW21. The first doping layer 231 may be between the first gate insulating layer 121 and the first source/drain region SD1. For example, the first doping layer 231 may be in contact with each of the first gate insulating layer 121, the first active pattern F21, the first plurality of nanosheets NW21 and the first source/drain region SD1.

As shown in FIG. 26, in the cross-sectional view taken along the first horizontal direction DR1, at least a portion of the first doping layer 231 may be between the first source/drain region SD1 and the first gate insulating layer 121. For example, between the first source/drain region SD1 and the first gate insulating layer 121, the first doping layer 231 may be in contact with the first source/drain region SD1. For example, the first doping layer 231 is not between the first source/drain region SD1 and the first plurality of nanosheets NW21. In some embodiments, the first source/drain region SD1 may directly contact the first plurality of nanosheets NW21 without the first doping layer 231 therebetween. For example, at least a portion of the first doping layer 231 may be more protruded toward the first source/drain region SD1 than the sidewall of the first plurality of nanosheets NW21 in the first horizontal direction DR1.

For example, at least a portion of the first doping layer 231 may overlap the uppermost nanosheet of the first plurality of nanosheets NW21 in the first horizontal direction DR1. For example, at least a portion of the sidewall of the first doping layer 231 in the first horizontal direction DR1 may be in contact with the uppermost nanosheet of the first plurality of nanosheets NW21. For example, the uppermost surface of the first doping layer 231 may be formed on the same plane as the upper surface of the uppermost nanosheet of the first plurality of nanosheets NW21, but the present disclosure is not limited thereto.

As shown in FIG. 27, in the cross-sectional view taken along the second horizontal direction DR2, the first doping layer 231 may be along the sidewalls and the upper surface of the first active pattern F21 protruded in the vertical direction DR3 on the upper surface of the field insulating layer 105. For example, a width of the first active pattern F21 in the second horizontal direction DR2, which is surrounded by the first doping layer 231, may be smaller than a width of the first active pattern F21 in the second horizontal direction DR2, which is surrounded by the field insulating layer 105. For example, the lowermost surface of the first doping layer 231 may be in contact with the upper surface of a portion of the first active pattern F21, which is surrounded by the field insulating layer 105. The first doping layer 231 may surround the sidewalls, the lower surface and the upper surface of each of the first plurality of nanosheets NW21 in the second horizontal direction DR2.

The first doping layer 231 may have a liner shape. For example, a thickness of the first doping layer 231 may be in the range of 2 Å to 15 Å. The first doping layer 231 may include, for example, silicon (Si) or silicon germanium (SiGe). For example, the first doping layer 231 may be doped with a second doping material that is a p-type doping material. That is, the NMOS region I on the surface of the first plurality of nanosheets NW21 on the NMOS region I of the substrate 100 may include silicon (Si) or silicon germanium (SiGe), which is doped with a p-type doping material. For example, the p-type doping material may include at least one of boron (B), aluminum (Al), gallium (Ga) or indium (In).

In the semiconductor device according to some embodiments of the present disclosure, the second doping layer 132 including silicon (Si) or silicon germanium (SiGe), which is doped with an n-type doping material, may be on the surface of the second plurality of nanosheets NW2 corresponding to a channel region of the PMOS transistor on the PMOS region II of the substrate 100, and the first doping layer 231 including silicon (Si) or silicon germanium (SiGe), which is doped with a p-type doping material, may be on the surface of the first plurality of nanosheets NW21 corresponding to a channel region of the NMOS transistor on the NMOS region I of the substrate 100. Therefore, the semiconductor device according to some other embodiments of the present disclosure may control (e.g., may control effectively) a threshold voltage of each of the PMOS transistor and the NMOS transistor.

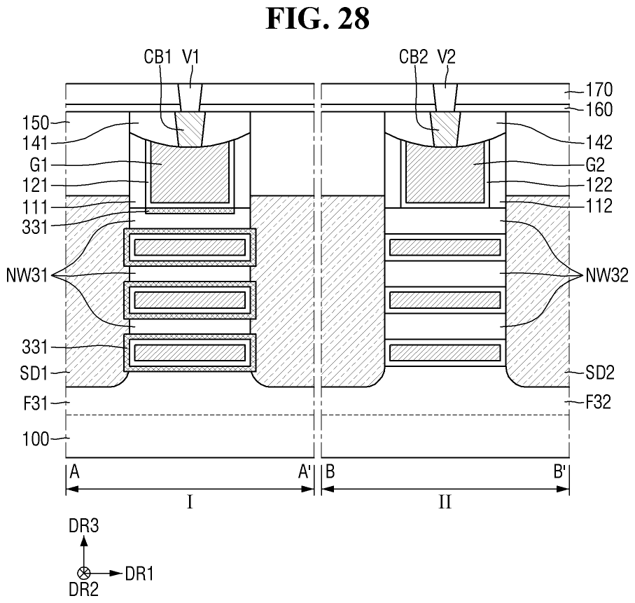

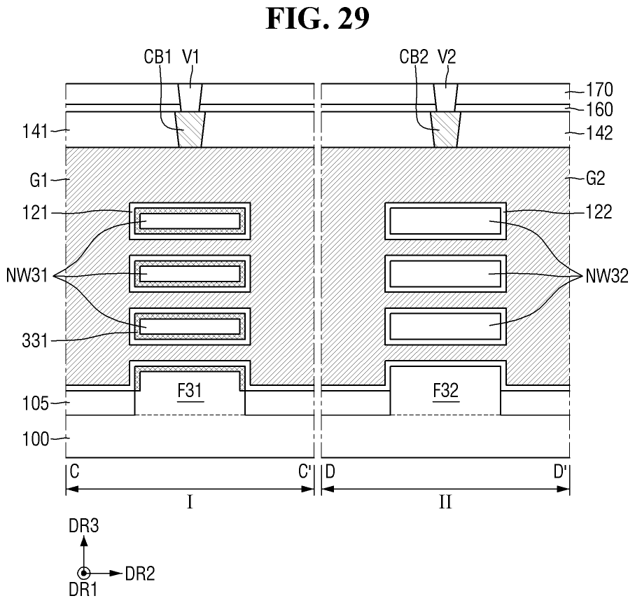

Hereinafter, a semiconductor device according to some other embodiments of the present disclosure will be described with reference to FIGS. 28 and 29. The following description will be based on differences from each of the semiconductor device shown in FIGS. 1 to 4 and the semiconductor device shown in FIGS. 26 and 27.

FIGS. 28 and 29 are cross-sectional views illustrating a semiconductor device according to some embodiments of the present disclosure.

Referring to FIGS. 28 and 29, in the semiconductor device according to some other embodiments of the present disclosure, a first doping layer 331 is on the NMOS region I of the substrate 100, and a doping layer is not on the PMOS region II of the substrate 100.

For example, each of a first active pattern F31, a first plurality of nanosheets NW31 and the first doping layer 331, which are on the NMOS region I of the substrate 100, may have the same structure as that of each of the first active pattern F21, the first plurality of nanosheets NW21 and the first doping layer 231, which are shown in FIG. 26, and thus a detailed description thereof will be omitted. For example, the second gate insulating layer 122 may be in contact with each of the second active pattern F32, a second plurality of nanosheets NW32 and the second source/drain region SD2.

In the semiconductor device according to some embodiments of the present disclosure, the first doping layer 331 including silicon (Si) or silicon germanium (SiGe), which is doped with a p-type doping material, may be on the surface of the first plurality of nanosheets NW31 corresponding to the channel region of the NMOS transistor on the NMOS region I of the substrate 100. Therefore, the semiconductor device according to some other embodiments of the present disclosure may control (e.g., may control effectively) the threshold voltage of the PMOS transistor.

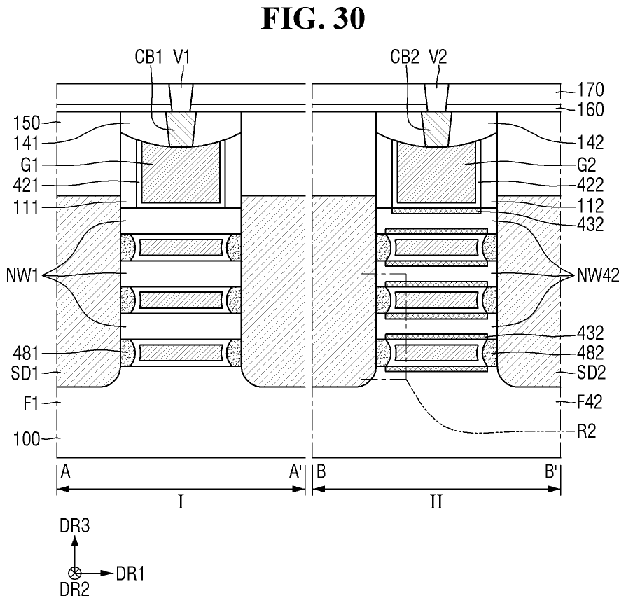

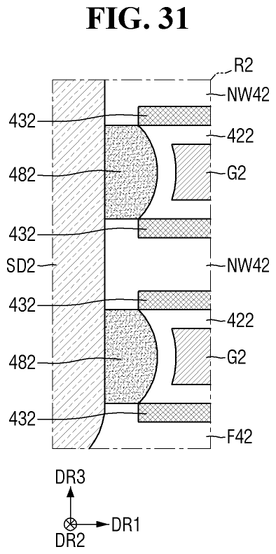

Hereinafter, a semiconductor device according to some other embodiments of the present disclosure will be described with reference to FIGS. 30 and 31. The following description will be based on differences from the semiconductor device shown in FIGS. 1 to 4.

FIG. 30 is a cross-sectional view illustrating a semiconductor device according to some embodiments of the present disclosure. FIG. 31 is an enlarged view illustrating a region R2 of FIG. 30.

Referring to FIGS. 30 and 31, a first inner spacer 481 may be on the NMOS region I of the substrate 100, and a second inner spacer 482 may be on the PMOS region II of the substrate 100.

For example, the first inner spacer 481 may be on both sidewalls of the first gate electrode G1 in the first horizontal direction DR1 between the first active pattern F1 and the lowermost nanosheet of the first plurality of nanosheets NW1. In addition, the first inner spacer 481 may be on both sidewalls of the first gate electrode G1 in the first horizontal direction DR1 between the first plurality of nanosheets NW1. The first inner spacer 481 may be between the first source/drain region SD1 and a first gate insulating layer 421 between the first active pattern F1 and the lowermost nanosheet of the first plurality of nanosheets NW1. In addition, the first inner spacer 481 may be between the first source/drain region SD1 and the first gate insulating layer 421 between the first plurality of nanosheets NW1. The first inner spacer 481 may be in contact with each of the first active pattern F1, the first plurality of nanosheets NW1, the first gate insulating layer 421 and the first source/drain region SD1.

For example, the second inner spacer 482 may be on both sidewalls of the second gate electrode G2 in the first horizontal direction DR1 between a second active pattern F42 and the lowermost nanosheet of a second plurality of nanosheets NW42. In addition, the second inner spacer 482 may be on both sidewalls of the second gate electrode G2 in the first horizontal direction DR1 between the second plurality of nanosheets NW42. The second inner spacer 482 may be between the second source/drain region SD2 and a second gate insulating layer 422 between the second active pattern F42 and the lowermost nanosheet of the second plurality of nanosheets NW42. In addition, the second inner spacer 482 may be between the second source/drain region SD2 and the second gate insulating layer 422 between the second plurality of nanosheets NW42. The second inner spacer 482 may be in contact with each of the second active pattern F42, the second plurality of nanosheets NW42, the second gate insulating layer 422 and the second source/drain region SD2.

Each of the first inner spacer 481 and second inner spacer 482 may include at least one of, for example, silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC) or their combination, but the present disclosure is not limited thereto.

For example, a second doping layer 432 may be between the second gate insulating layer 422 and the second active pattern F42. The second doping layer 432 may be between the second gate insulating layer 422 and the second plurality of nanosheets NW42. However, the second doping layer 432 is not between the second gate insulating layer 422 and the second source/drain region SD2. For example, the second doping layer 432 may be in contact with each of the second gate insulating layer 422, the second active pattern F42 and the second plurality of nanosheets NW42. For example, the second doping layer 432 may be in contact with the second inner spacer 482. However, the second doping layer 432 may not be in contact with the second source/drain region SD2.

As shown in FIGS. 30 and 31, in the cross-sectional view taken along the first horizontal direction DR1, at least a portion of the second doping layer 432 may overlap each of the second plurality of nanosheets NW42 in the first horizontal direction DR1. For example, at least a portion of the sidewall of the second doping layer 432 in the first horizontal direction DR1 may be in contact with each of the second plurality of nanosheets NW42. For example, the uppermost surface of the second doping layer 432 may be formed on the same plane as the upper surface of the uppermost nanosheet of the second plurality of nanosheets NW42, but the present disclosure is not limited thereto. For example, at least a portion of the second doping layer 432 may overlap the second active pattern F42 in the first horizontal direction DR1. For example, at least a portion of the sidewall of the second doping layer 432 in the first horizontal direction DR1 may be in contact with the second active pattern F42.

In the cross-sectional view taken along the first horizontal direction DR1, a thickness of each of the second plurality of nanosheets NW42 that are in contact with the second source/drain region SD2 may be greater than that of each of the second plurality of nanosheets NW42 in the vertical direction DR3, which are between the second doping layers 432.

Hereinafter, a semiconductor device according to some embodiments of the present disclosure will be described with reference to FIGS. 30 to 36. The following description will be based on differences from the semiconductor device shown in FIGS. 2 to 25.

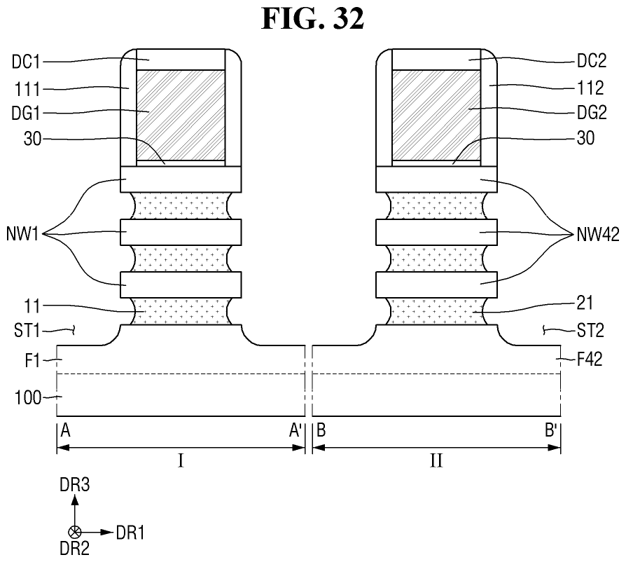

FIGS. 32 to 36 are views illustrating intermediate steps to describe a method for fabricating a semiconductor device according to some embodiments of the present disclosure.

Referring to FIG. 32, after the fabricating process shown in FIGS. 5 to 10 is performed, a portion of a sidewall of the first sacrificial layer 11 and a portion of a sidewall of the second sacrificial layer 21 may be etched. For example, both sidewalls of the first sacrificial layer 11 in the first horizontal direction DR1 may be formed to be concave toward the center of the first sacrificial layer 11. Both sidewalls of the second sacrificial layer 21 in the first horizontal direction DR1 may be formed to be concave toward the center of the second sacrificial layer 21.

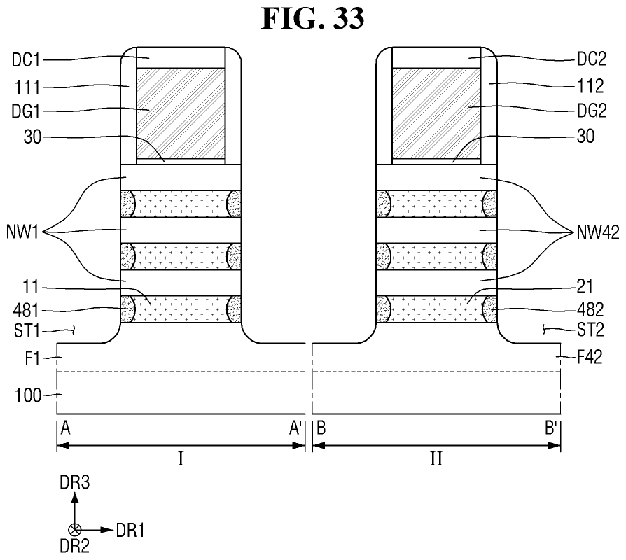

Referring to FIG. 33, the first inner spacer 481 may be formed in the etched portion of the sidewall of the first sacrificial layer 11. In addition, the second inner spacer 482 may be formed in the etched portion of the sidewall of the second sacrificial layer 21.

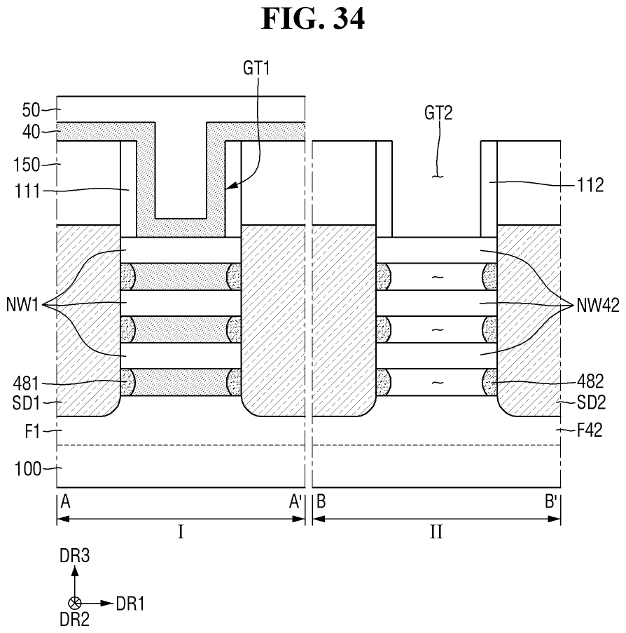

Referring to FIG. 34, after the first inner spacer 481 and the second inner spacer 482 are formed, the fabricating process shown in FIGS. 11 to 15 may be performed. A mask pattern 50 may be formed to cover the liner layer 40 on the NMOS region I of the substrate 100. Subsequently, the liner layer 40 formed on the PMOS region II of the substrate 100 may be etched.

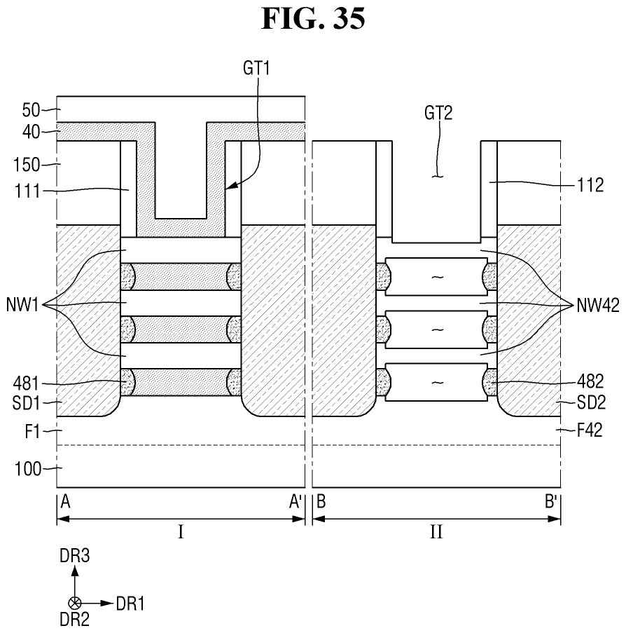

Referring to FIG. 35, a portion of the exposed surface of the second plurality of nanosheets NW42 and a portion of the exposed surface of the second active pattern F42 may be etched through the second gate trench GT2. For example, a portion of the second active pattern F42, which is in contact with the second inner spacer 482, and a portion of the second plurality of nanosheets NW42 are not etched. In addition, a portion of the second plurality of nanosheets NW42, which is in contact with the second gate spacer 112, is not etched.

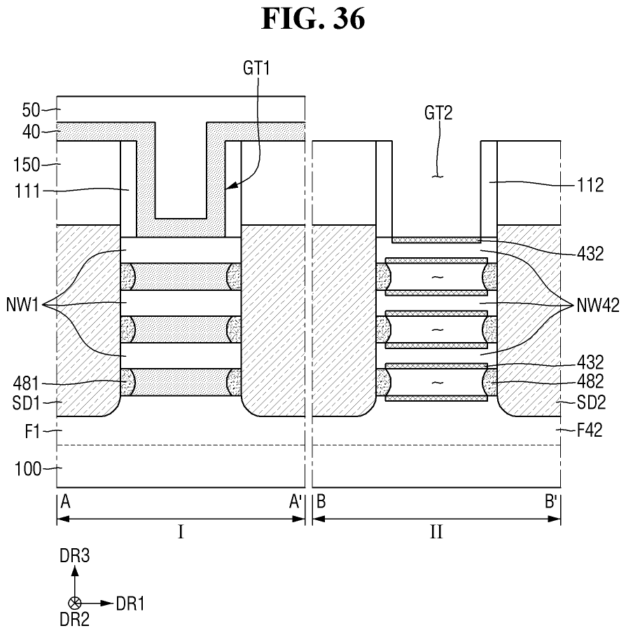

Referring to FIG. 36, the second doping layer 432 may be formed in each of the etched portions of the second plurality of nanosheets NW42 and the etched portion of the second active pattern F42. That is, each of the etched portions of the second plurality of nanosheets NW42 and the etched portions of the second active pattern F42 may be replaced with the second doping layer 432. For example, the second doping layer 432 may be formed by being epitaxially grown from each of the second plurality of nanosheets NW42 and the second active pattern F42.

Referring to FIG. 30, after the second doping layer 432 is formed, the fabricating process shown in FIGS. 22 to 25 may be performed. Subsequently, the first gate contact CB1, the second gate contact CB2, the etch stop layer 160, the second interlayer insulating layer 170, the first via V1 and the second via V2 may be formed. Through this fabricating process, the semiconductor device shown in FIG. 30 may be fabricated.

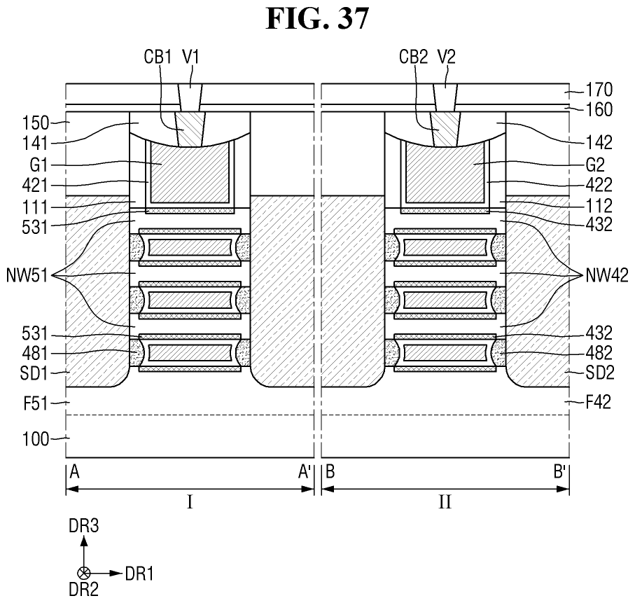

Hereinafter, a semiconductor device according to some embodiments of the present disclosure will be described with reference to FIG. 37. The following description will be based on differences from the semiconductor device shown in FIG. 30.

FIG. 37 is a cross-sectional view illustrating a semiconductor device according to some embodiments of the present disclosure.

Referring to FIG. 37, in the semiconductor device according to some embodiments of the present disclosure, a first doping layer 531 may be on the NMOS region I of the substrate 100.

For example, the first doping layer 531 may be between the first gate insulating layer 421 and a first active pattern F51. The first doping layer 531 may be between the first gate insulating layer 421 and a first plurality of nanosheets NW51. The first doping layer 531 may not be between the first gate insulating layer 421 and the first source/drain region SD1. For example, the first doping layer 531 may be in contact with each of the first gate insulating layer 421, the first active pattern F51 and the first plurality of nanosheets NW51. For example, the first doping layer 531 may be in contact with the first inner spacer 481. However, the first doping layer 531 may not be in contact with the first source/drain region SD1.

As shown in FIG. 37, in the cross-sectional view taken along the first horizontal direction DR1, at least a portion of the first doping layer 531 may overlap each of the first plurality of nanosheets NW51 in the first horizontal direction DR1. For example, at least a portion of sidewalls of the first doping layer 531 in the first horizontal direction DR1 may be in contact with each of the first plurality of nanosheets NW51. For example, the uppermost surface of the first doping layer 531 may be formed on the same plane as the upper surface of the uppermost nanosheet of the first plurality of nanosheets NW51, but the present disclosure is not limited thereto. For example, at least a portion of the first doping layer 531 may overlap the first active pattern F51 in the first horizontal direction DR1. For example, at least a portion of the sidewalls of the first doping layer 531 in the first horizontal direction DR1 may be in contact with the first active pattern F51.

In the cross-sectional view taken along the first horizontal direction DR1, a thickness of each of the first plurality of nanosheets NW51 in a portion that is in contact with the first source/drain region SD1 may be greater than that of each of the first plurality of nanosheets NW51 in the vertical direction DR3, which are between the first doping layers 531.

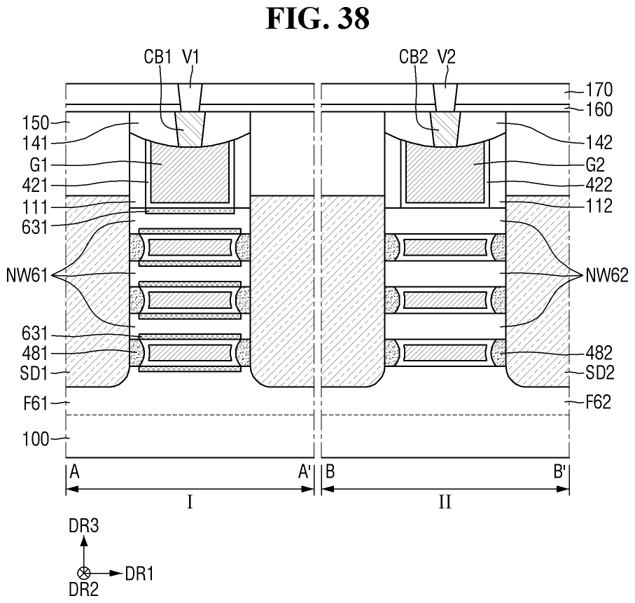

Hereinafter, a semiconductor device according to some embodiments of the present disclosure will be described with reference to FIG. 38. The following description will be based on differences from the semiconductor device shown in FIG. 30.

FIG. 38 is a cross-sectional view illustrating a semiconductor device according to some embodiments of the present disclosure.

Referring to FIG. 38, a first doping layer 631 may be on the NMOS region I of the substrate 100, and a doping layer may not be on (and may be absent from) the PMOS region II of the substrate 100.

For example, each of a first active pattern F61, a first plurality of nanosheets NW61 and the first doping layer 631, which are on the NMOS region I of the substrate 100, may have the same structure as that of each of the first active pattern F51, the first plurality of nanosheets NW51 and the first doping layer 531, which are shown in FIG. 37, and thus a detailed description thereof will be omitted. For example, the second gate insulating layer 422 may be in contact with each of a second active pattern F62, a second plurality of nanosheets NW62 and the second source/drain region SD2.

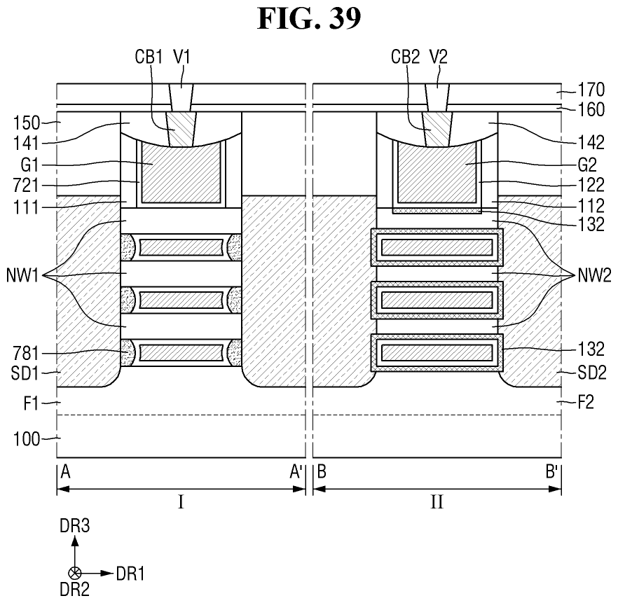

Hereinafter, a semiconductor device according to some embodiments of the present disclosure will be described with reference to FIG. 39. The following description will be based on differences from the semiconductor device shown in FIGS. 1 to 4.

FIG. 39 is a cross-sectional view illustrating a semiconductor device according to some embodiments of the present disclosure.

Referring to FIG. 39, in the semiconductor device according to some embodiments of the present disclosure, a first inner spacer 781 may be on the NMOS region I of the substrate 100.

For example, the first inner spacer 781 may be on both sidewalls of the first gate electrode Gl in the first horizontal direction DR1 between the first active pattern F1 and the lowermost nanosheet of the first plurality of nanosheets NW1. In addition, the first inner spacer 781 may be on both sidewalls of the first gate electrode G1 in the first horizontal direction DR1 between the first plurality of nanosheets NW1. The first inner spacer 781 may be between the first source/drain region SD1 and a first gate insulating layer 721 between the first active pattern F1 and the lowermost nanosheet of the first plurality of nanosheets NW1. In addition, the first inner spacer 781 may be between the first source/drain region SD1 and the first gate insulating layer 721 between the first plurality of nanosheets NW1. The first inner spacer 781 may be in contact with cach of the first active pattern F1, the first plurality of nanosheets NW1, the first gate insulating layer 721 and the first source/drain region SD1.

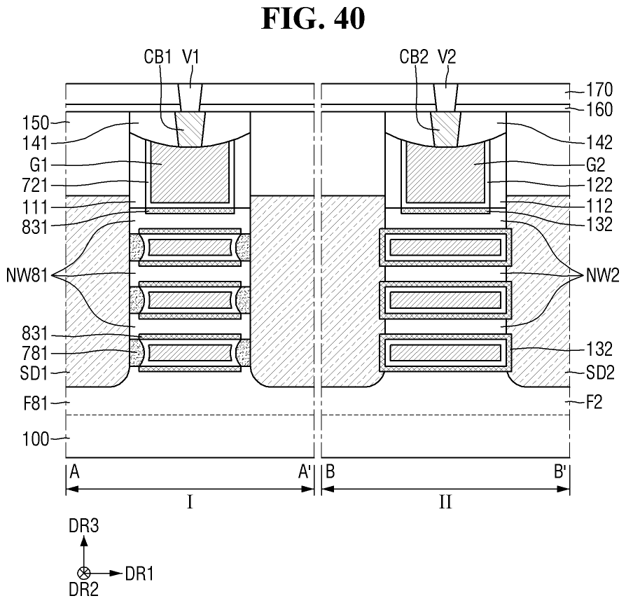

Hereinafter, a semiconductor device according to some embodiments of the present disclosure will be described with reference to FIG. 40. The following description will be based on differences from the semiconductor device shown in FIG. 39.

FIG. 40 is a cross-sectional view illustrating a semiconductor device according to some embodiments of the present disclosure.

Referring to FIG. 40, in the semiconductor device according to some embodiments of the present disclosure, a first doping layer 831 may be on the NMOS region I of the substrate 100 on which the first inner spacer 781 is provided.

For example, the first doping layer 831 may be disposed between the first gate insulating layer 721 and a first active pattern F81. The first doping layer 831 may be between the first gate insulating layer 721 and a first plurality of nanosheets NW81. The first doping layer 831 may not be between the first gate insulating layer 721 and the first source/drain region SD1. For example, the first doping layer 831 may be in contact with each of the first gate insulating layer 721, the first active pattern F81 and the first plurality of nanosheets NW81. For example, the first doping layer 831 may be in contact with the first inner spacer 781. However, the first doping layer 831 may not be in contact with the first source/drain region SD1.

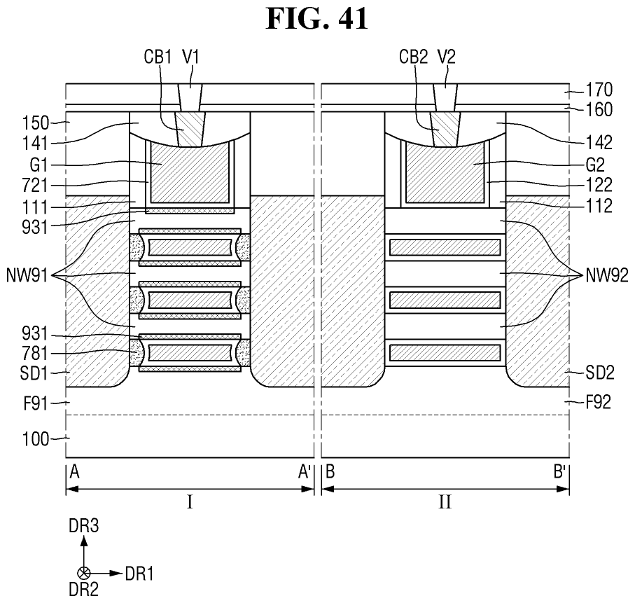

Hereinafter, a semiconductor device according to some embodiments of the present disclosure will be described with reference to FIG. 41. The following description will be based on differences from the semiconductor device shown in FIG. 39.

FIG. 41 is a cross-sectional view illustrating a semiconductor device according to some embodiments of the present disclosure.

Referring to FIG. 41, in the semiconductor device according to some embodiments of the present disclosure, a first doping layer 931 may be on the NMOS region I of the substrate 100 on which the first inner spacer 781 is provided, and a doping layer is not on the PMOS region II of the substrate 100 in which an inner spacer is not provided.

For example, each of a first active pattern F91, a first plurality of nanosheets NW91 and the first doping layer 931, which are on the NMOS region I of the substrate 100, may have the same structure as that of each of the first active pattern F81, the first plurality of nanosheets NW81 and the first doping layer 831, which are shown in FIG. 40, and thus a detailed description thereof will be omitted. For example, the second gate insulating layer 122 may be in contact with each of a second active pattern F92, a second plurality of nanosheets NW92 and the second source/drain region SD2.

Although some embodiments according to the present disclosure have been described with reference to the accompanying drawings, it will be apparent to those skilled in the art that the inventive concepts provided herein may be embodied in various forms without being limited to the above-described embodiments and can be embodied in other specific forms without departing from technical spirits and essential characteristics of the present disclosure. Thus, the above embodiments are to be considered in all respects as illustrative and not restrictive.

What is claimed is:

1. A semiconductor device comprising:
a substrate;
an active pattern extended in a first horizontal direction on the substrate;
a plurality of nanosheets stacked and spaced apart from each other in a vertical direction on the active pattern;
a gate electrode extended in a second horizontal direction different from the first horizontal direction on the active pattern, the gate electrode surrounding the plurality of nanosheets;
a source/drain region on both sides of the plurality of nanosheets in the first horizontal direction on the active pattern;
a gate insulating layer between the plurality of nanosheets and the gate electrode; and
a doping layer between the plurality of nanosheets and the gate insulating layer, the doping layer including silicon (Si) or silicon germanium (SiGe), and the doping layer doped with a doping material, at least a portion of the doping layer overlapping an uppermost nanosheet of the plurality of nanosheets in the first horizontal direction.

2. The semiconductor device of claim 1, wherein at least a portion of a sidewall of the doping layer in the first horizontal direction is in contact with the uppermost nanosheet of the plurality of nanosheets.

3. The semiconductor device of claim 1, wherein an uppermost surface of the doping layer is formed on the same plane as an upper surface of the uppermost nanosheet of the plurality of nanosheets.

4. The semiconductor device of claim 1, wherein at least a portion of the doping layer is in contact with the active pattern.

5. The semiconductor device of claim 1, wherein the substrate is defined as a PMOS region, and the doping material is an n-type doping material.

6. The semiconductor device of claim 1, wherein the substrate is defined as an NMOS region, and the doping material is a p-type doping material.

7. The semiconductor device of claim 1, wherein at least a portion of the doping layer is between the source/drain region and the gate insulating layer.

8. The semiconductor device of claim 7, wherein at least a portion of the doping layer is in contact with the source/drain region.

9. The semiconductor device of claim 1, further comprising an inner spacer on both sidewalls of the gate electrode in the first horizontal direction between the plurality of nanosheets, the inner spacer being in contact with the source/drain region and each of the plurality of nanosheets.

10. The semiconductor device of claim 9, wherein a thickness of a lowermost nanosheet of the plurality of nanosheets in the vertical direction in a portion that is in contact with the source/drain region is greater than a thickness of the lowermost nanosheet of the plurality of nanosheets in the vertical direction in a portion between the doping layers.

11. The semiconductor device of claim 9, wherein at least a portion of a sidewall of the doping layer in the first horizontal direction is in contact with a lowermost nanosheet of the plurality of nanosheets.

12. The semiconductor device of claim 9, wherein at least a portion of a sidewall of the doping layer in the first horizontal direction is in contact with the active pattern.

13. A semiconductor device comprising:
a substrate in which an NMOS region and a PMOS region are defined;
a first active pattern extended in a first horizontal direction on the NMOS region of the substrate;
a second active pattern extended in the first horizontal direction on the PMOS region of the substrate;
a first plurality of nanosheets stacked and spaced apart from each other in a vertical direction on the first active pattern;
a second plurality of nanosheets stacked and spaced apart from each other in the vertical direction on the second active pattern;
a first gate electrode extended in a second horizontal direction different from the first horizontal direction on the first active pattern, the first gate electrode surrounding the first plurality of nanosheets;
a second gate electrode extended in the second horizontal direction on the second active pattern, the second gate electrode surrounding the second plurality of nanosheets;
a first source/drain region on both sides of the first plurality of nanosheets in the first horizontal direction on the first active pattern;
a second source/drain region on both sides of the second plurality of nanosheets in the first horizontal direction on the second active pattern;
a first gate insulating layer between the first plurality of nanosheets and the first gate electrode;
a second gate insulating layer between the second plurality of nanosheets and the second gate electrode; and
a first doping layer between the second plurality of nanosheets and the second gate insulating layer, the first doping layer including silicon (Si) or silicon germanium (SiGe), the first doping layer doped with an n-type doping material, at least a portion of the first doping layer overlapping an uppermost nanosheet of the second plurality of nanosheets in the first horizontal direction.

14. The semiconductor device of claim 13, wherein at least a portion of the first doping layer is between the second source/drain region and the second gate insulating layer.

15. The semiconductor device of claim 13, further comprising a first inner spacer on both sidewalls of the first gate electrode in the first horizontal direction between the first plurality of nanosheets, the first inner spacer being in contact with the first source/drain region and each of the first plurality of nanosheets.

16. The semiconductor device of claim 13, further comprising a second inner spacer on both sidewalls of the second gate electrode in the first horizontal direction between the second plurality of nanosheets, the second inner spacer being in contact with the second source/drain region and each of the second plurality of nanosheets.

17. The semiconductor device of claim 13, further comprising a second doping layer between the first plurality of nanosheets and the first gate insulating layer, the second doping layer including silicon (Si) or silicon germanium (SiGe), the second doping layer doped with a p-type doping material, at least a portion of the second doping layer overlapping an uppermost nanosheet of the first plurality of nanosheets in the first horizontal direction.

18. A semiconductor device comprising:
a substrate in which an NMOS region and a PMOS region are defined;
a first active pattern extended in a first horizontal direction on the NMOS region of the substrate;
a second active pattern extended in the first horizontal direction on the PMOS region of the substrate;
a first plurality of nanosheets stacked and spaced apart from each other in a vertical direction on the first active pattern;
a second plurality of nanosheets stacked and spaced apart from each other in the vertical direction on the second active pattern;
a first gate electrode extended in a second horizontal direction different from the first horizontal direction on the first active pattern, the first gate electrode surrounding the first plurality of nanosheets;
a second gate electrode extended in the second horizontal direction on the second active pattern, the second gate electrode surrounding the second plurality of nanosheets;
a first source/drain region on both sides of the first plurality of nanosheets in the first horizontal direction on the first active pattern;
a second source/drain region on both sides of the second plurality of nanosheets in the first horizontal direction on the second active pattern;
a first gate insulating layer between the first plurality of nanosheets and the first gate electrode;
a second gate insulating layer between the second plurality of nanosheets and the second gate electrode; and
a first doping layer between the first plurality of nanosheets and the first gate insulating layer, the first doping layer including silicon (Si) or silicon germanium (SiGe), the first doping layer doped with a p-type doping material, at least a portion of the first doping layer overlapping an uppermost nanosheet of the first plurality of nanosheets in the first horizontal direction.

19. The semiconductor device of claim 18, wherein at least a portion of the first doping layer is between the first source/drain region and the first gate insulating layer.

20. The semiconductor device of claim 18, further comprising a second doping layer between the second plurality of nanosheets and the second gate insulating layer, the second doping layer including silicon (Si) or silicon germanium (SiGe), the second doping layer doped with an n-type doping material, at least a portion of the second doping layer overlapping an uppermost nanosheet of the second plurality of nanosheets in the first horizontal direction.
